(19) United States
(12) Patent Application Publication
(10) Pub. No.: US 2025/0350383 A1
(43) Pub. Date: Nov. 13, 2025

(54) METHODS AND APPARATUS FOR LEVERAGING TRANSFER LEARNING FOR CHANNEL STATE INFORMATION ENHANCEMENT

(71) Applicant: InterDigital Patent Holdings, Inc., Wilmington, DE (US)

(72) Inventors: Tejaswinee Lutchoomun, Montreal (CA); Patrick Tooher, Montreal (CA); Mihaela Beluri, Jericho, NY (US); Yugeswar Deenoo Narayanan Thangaraj, Chalfont, PA (US); Akshay Malhotra, San Jose, CA (US); Moon IL Lee, Melville, NY (US); Satyanarayana Katla, London (GB)

(21) Appl. No.: 18/860,105

(22) PCT Filed: Apr. 26, 2023
(86) PCT No.: PCT/US2023/019994

§ 371 Date: Oct. 25, 2024

Related U.S. Application Data
(60) Provisional application No. 63/335,287, filed on Apr. 27, 2022.

(51) Int. Cl. H04B 17/336; H04B 7/06; H04B 17/391

(52) U.S. Cl. CPC H04B 17/336; H04B 7/0626; H04B 17/3913

(57) ABSTRACT

Methods and apparatus for leveraging transfer learning of one Wireless Transmit/Receive Unit (WTRU) to benefit another WTRU are provided. One method may include the WTRU receiving AI/ML model configuration information indicating one or more AI/ML models available from the network node, a profile associated with the AI/ML models, and a training convergence threshold. Based at least on the profile(s), the WTRU determining that the one or more AI/ML models are not suitable for use by the WTRU, and sending first information indicating that the one or more AI/ML models are not suitable for the WTRU and/or that the WTRU will be training a local AI/ML model. The method may then include training the local AI/ML model according to the convergence threshold, receiving a request to transfer AI/ML model parameters, and sending an indication of the AI/ML model parameters associated with the trained local AI/ML model to the network node.

### CROSS-REFERENCE TO RELATED APPLICATIONS

This application claims the benefit of U.S. Provisional Application No. 63/335,287 filed Apr. 27, 2022. The contents of this earlier filed application are hereby incorporated by reference in their entirety.

### FIELD

The present disclosure is generally directed to the field of wireless communications networks. For example, one or more embodiments disclosed herein may relate to methods, apparatuses, systems, and/or procedures for leveraging the learning of one Wireless Transmit/Receive Unit (WTRU) to benefit another WTRU.

### SUMMARY

Certain embodiments described herein may provide methods, apparatuses, systems and/or procedures for leveraging transfer learning of one Wireless Transmit/Receive Unit (WTRU) to benefit another WTRU. An embodiment may be directed to a method that may include the WTRU receiving AI/ML model configuration information indicating one or more AI/ML models available from the network node, a profile associated with the AI/ML models (e.g., a respective profile that is associated with each of the AI/ML models), and a training convergence threshold. Based at least on the one or more profiles, the WTRU determining that the one or more AI/ML models are not suitable for use by the WTRU, and sending first information indicating that the one or more AI/ML models are not suitable for the WTRU and/or that the WTRU will be training a local AI/ML model. The method may then include training the local AI/ML model according to the convergence threshold, receiving a request to transfer AI/ML model parameters, and sending an indication of the AI/ML model parameters associated with the trained local AI/ML model to the network node.

An embodiment may be directed to an apparatus that includes circuitry, including any of a processor, memory, receiver and/or transmitter. The circuitry may be configured to receive AI/ML model configuration information indicating one or more AI/ML models available from the network node, a profile associated with the AI/ML models, and a training convergence threshold. Based at least on the one or more profiles, the circuitry may be configured to determine that the one or more AI/ML models are not suitable for use by the WTRU, and to send first information indicating that the one or more AI/ML models are not suitable for the WTRU and/or that the WTRU will be training a local AI/ML model. The circuitry may be configured to train the local AI/ML model according to the convergence threshold, receive a request to transfer AI/ML model parameters, and send an indication of the AI/ML model parameters associated with the trained local AI/ML model to the network node.

### BRIEF DESCRIPTION OF THE DRAWINGS

A more detailed understanding may be had from the detailed description below, given by way of example in conjunction with the drawings appended hereto. Figures in such drawings, like the detailed description, are exemplary. As such, the Figures and the detailed description are not to be considered limiting, and other equally effective examples are possible and likely. Furthermore, like reference numerals (“ref.”) in the Figures (“FIGS.”) indicate like elements, and wherein:

FIG. 1A is a system diagram illustrating an example communications system in which one or more disclosed embodiments may be implemented;

FIG. 1B is a system diagram illustrating an example wireless transmit/receive unit (WTRU) that may be used within the communications system illustrated in FIG. 1A according to an embodiment;

FIG. 1C is a system diagram illustrating an example radio access network (RAN) and an example core network (CN) that may be used within the communications system illustrated in FIG. 1A according to an embodiment;

FIG. 1D is a system diagram illustrating a further example RAN and a further example CN that may be used within the communications system illustrated in FIG. 1A according to an embodiment;

FIG. 2 is diagram illustrating an example of a configuration for CSI reporting settings, resource settings, and links;

FIG. 3 is a diagram illustrating codebook-based precoding with feedback information;

FIG. 4 is a signal flow diagram of a method and apparatus for model transfer from an Artificial Intelligence/Machine Learning (AI/ML or AIML) model trainer in accordance with an embodiment;

FIG. 5A is a signal flow diagram of a method and apparatus for model transfer from an AI/ML model user in accordance with an embodiment; and

FIG. 5B is a signal flow diagram of a method and apparatus for UL and/or DL model transfer from/to one or more UEs, according to an embodiment; and

FIG. 6 is a flow diagram of a method, according to an embodiment.

### DETAILED DESCRIPTION

In the following detailed description, numerous specific details are set forth to provide a thorough understanding of embodiments and/or examples disclosed herein. However, it will be understood that such embodiments and examples may be practiced without some or all of the specific details set forth herein. In other instances, well-known methods, procedures, components, and circuits have not been described in detail, so as not to obscure the following description. Further, embodiments and examples not specifically described herein may be practiced in lieu of, or in combination with, the embodiments and other examples described, disclosed, or otherwise provided explicitly, implicitly and/or inherently (collectively “provided”) herein.

Although various embodiments are described and/or claimed herein in which an apparatus, system, device, etc. and/or any element thereof carries out an operation, process, algorithm, function, etc. and/or any portion thereof, it is to be understood that any embodiments described and/or claimed herein assume that any apparatus, system, device, etc. and/or any element thereof is configured to carry out any operation, process, algorithm, function, etc. and/or any portion thereof.

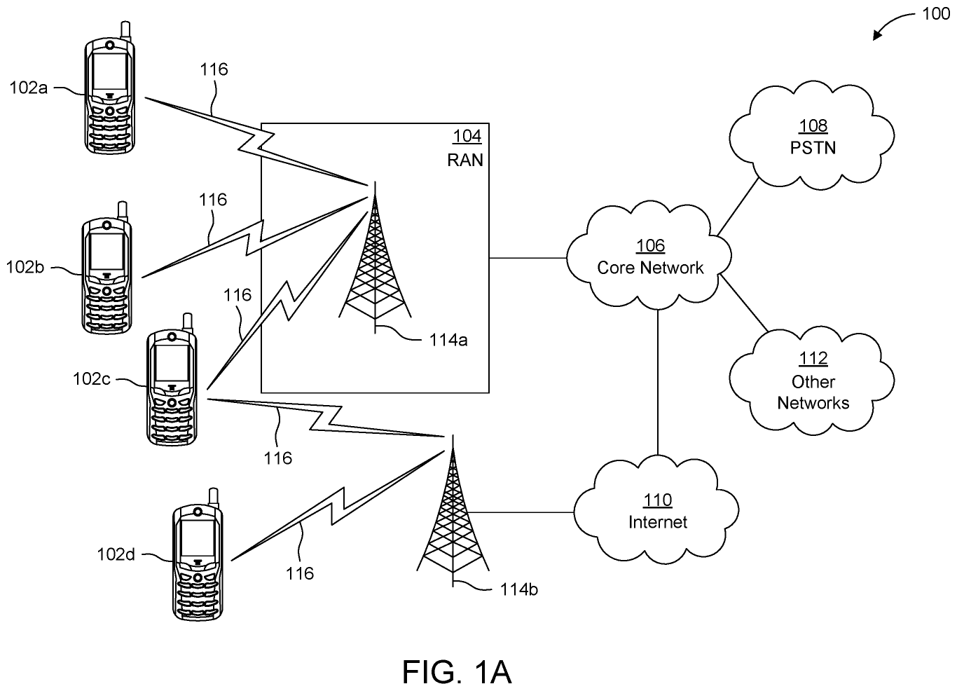

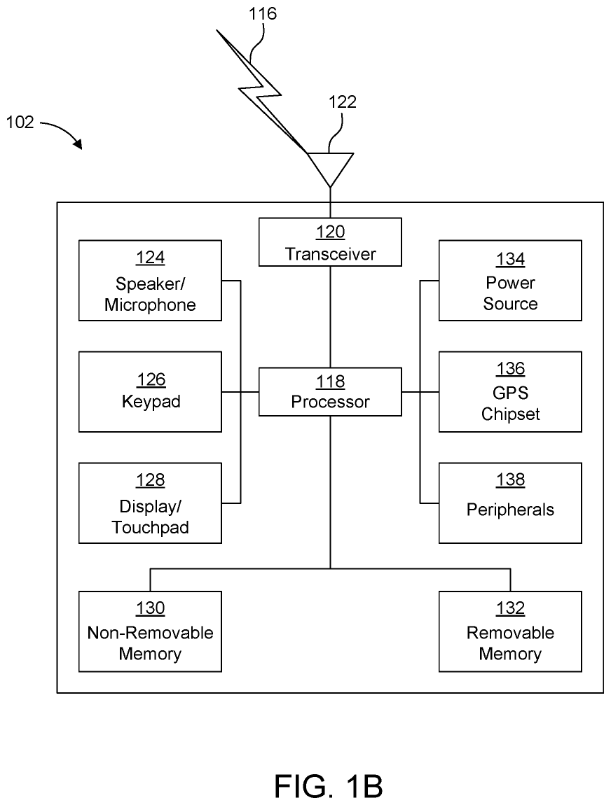

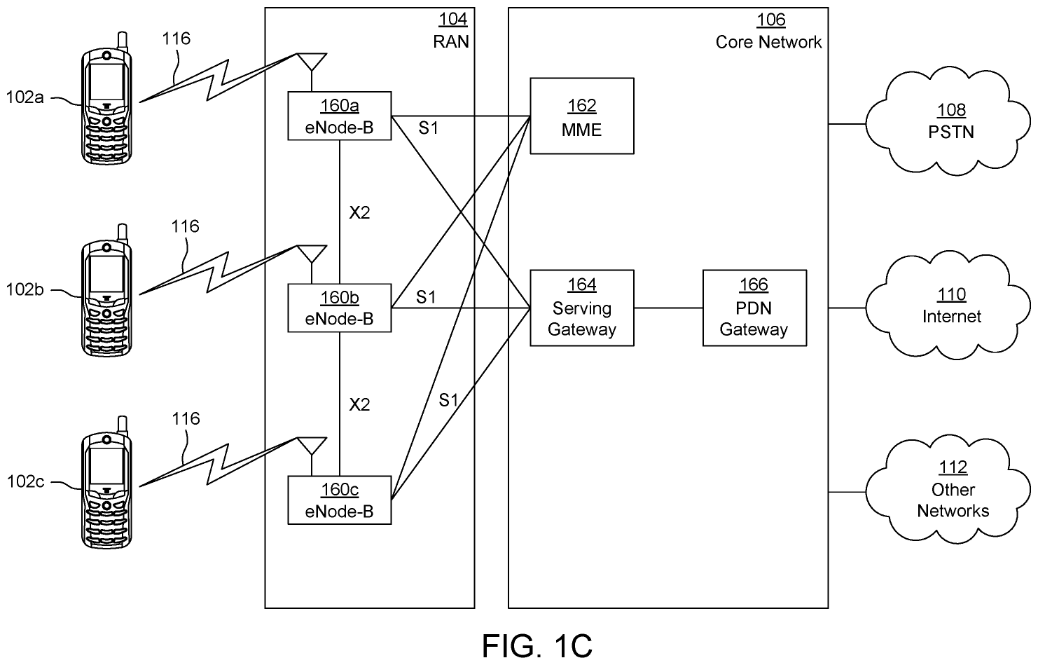

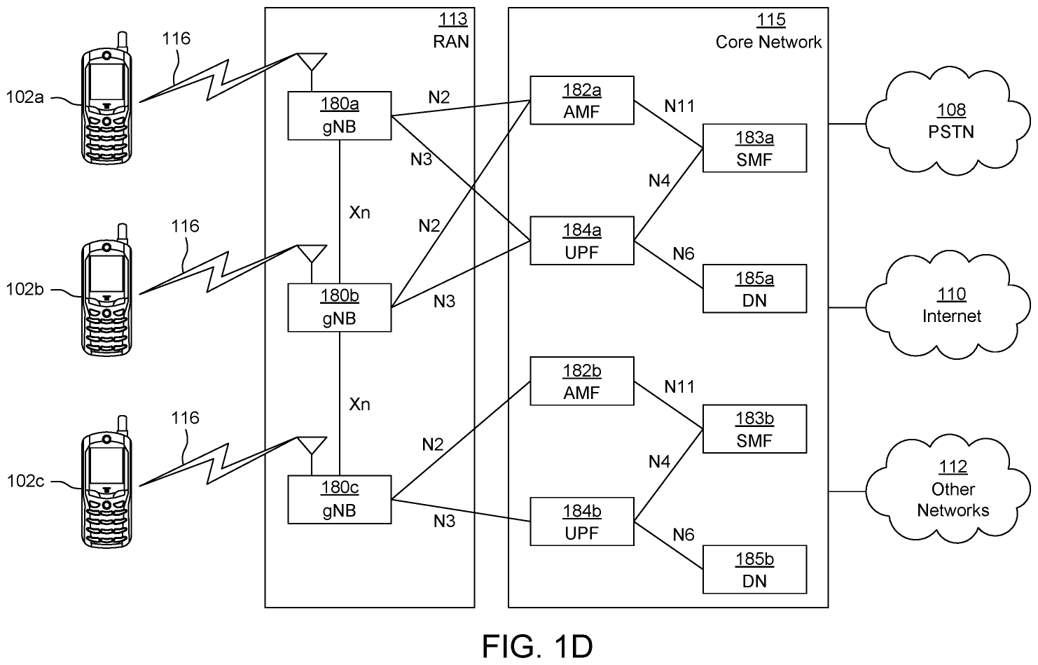

The methods, apparatuses and systems provided herein are well-suited for communications involving both wired and wireless networks. Wired networks are well-known. An overview of various types of wireless devices and infrastructure is provided with respect to FIGS. 1A-1D, where various elements of the network may utilize, perform, be arranged in accordance with and/or be adapted and/or configured for the methods, apparatuses and systems provided herein.

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104/113, a CN 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106/115, the Internet 110, and/or the other networks 112. By way of example, the base stations 114a, 114b may be a base transceiver station (BTS), a Node-B, an eNode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 116 using wideband CDMA (WCDMA). WCDMA may include communication protocols such as High-Speed Packet Access (HSPA) and/or Evolved HSPA (HSPA+). HSPA may include High-Speed Downlink Packet Access (HSDPA) and/or High-Speed Uplink Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., an eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VOIP) services to one or more of the WTRUs 102a, 102b, 102c, 102d. The data may have varying quality of service (QOS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing a NR radio technology, the CN 106/115 may also be in communication with another RAN (not shown) employing a GSM, UMTS, CDMA 2000, WIMAX, E-UTRA, or WiFi radio technology.

The CN 106/115 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/113 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the uplink (e.g., for transmission) and downlink (e.g., for reception) may be concurrent and/or simultaneous. The full duplex radio may include an interference management unit 139 to reduce and or substantially eliminate self-interference via either hardware (e.g., a choke) or signal processing via a processor (e.g., a separate processor (not shown) or via processor 118). In an embodiment, the WTRU 102 may include a half-duplex radio for which transmission and reception of some or all of the signals (e.g., associated with particular subframes for either the uplink (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the uplink (UL) and/or downlink (DL), and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (or PGW) 166. While each of the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have an access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier Sense Multiple Access with Collision Avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHZ, 80 MHZ, and/or 160 MHz wide channels. The 40 MHZ, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz and 20 MHz bandwidths in the TV White Space (TVWS) spectrum, and 802.11ah supports 1 MHZ, 2 MHz, 4 MHZ, 8 MHz, and 16 MHz bandwidths using non-TVWS spectrum. According to a representative embodiment, 802.11ah may support Meter Type Control/Machine-Type Communications, such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHZ, 8 MHZ, 16 MHZ, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 180b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (COMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the uplink (UL) and/or downlink (DL), support of network slicing, dual connectivity, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 115 shown in FIG. 1D may include at least one AMF 182a, 182b, at least one UPF 184a, 184b, at least one Session Management Function (SMF) 183a, 183b, and possibly a Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different PDU sessions with different requirements), selecting a particular SMF 183a, 183b, management of the registration area, termination of NAS signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for machine type communication (MTC) access, and/or the like. The AMF a82a, 182b may provide a control plane function for switching between the RAN 113 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-b, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

Certain example embodiments may relate to Channel State Information reporting. Channel State Information (CSI), which may include at least one of the following: channel quality index (CQI), rank indicator (RI), precoding matrix index (PMI), an L1 channel measurement (e.g., RSRP such as L1-RSRP, or SINR), CSI-RS resource indicator (CRI), SS/PBCH block resource indicator (SSBRI), layer indicator (LI) and/or any other measurement quantity measured by the WTRU from the configured reference signals (e.g., CSI-RS or SS/PBCH block or any other reference signal). More particularly, one or more embodiments disclosed herein may relate to methods, apparatuses, systems, and/or procedures for leveraging transfer learning to achieve Channel State Information (CSI) feedback enhancement, such as overhead reduction, improved accuracy and prediction.

Some example embodiments may provide a CSI reporting framework. A WTRU may be configured to report the CSI through the uplink control channel on the Physical Uplink Control Channel (PUCCH), or per the gNB's request on an Uplink Physical Shared Channel (UL PUSCH) grant. Depending on the configuration, CSI-RS may cover the full bandwidth of a BandWidth Part (BWP) or just a fraction of it. Within the CSI-RS bandwidth, CSI-RS may be configured in each Physical Resource Block (PRB) or every other PRB. In the time domain, CSI-RS resources can be configured either periodically, semi-persistently, or aperiodically. Semi-persistent CSI-RS is similar to periodic CSI-RS, except that the resource can be (de)-activated by MAC Control Elements (CEs); and the WTRU reports related measurements only when the resource is activated. For aperiodic CSI-RS, the WTRU is triggered to report measured CSI-RS on PUSCH by request in a DCI (Downlink Control Information). Periodic reports are carried over the PUCCH, while semi-persistent reports can be carried either on PUCCH or PUSCH. The reported CSI may be used by the scheduler when allocating optimal resource blocks possibly based on channel's time-frequency selectivity, determining precoding matrices, beams, and/or transmission modes, and selecting suitable Modulation and Coding Schemes (MCSs). The reliability, accuracy, and timeliness of WTRU CSI reports may be critical to meeting Ultra-Reliable and Low Latency Communications (URLLC) service requirements.

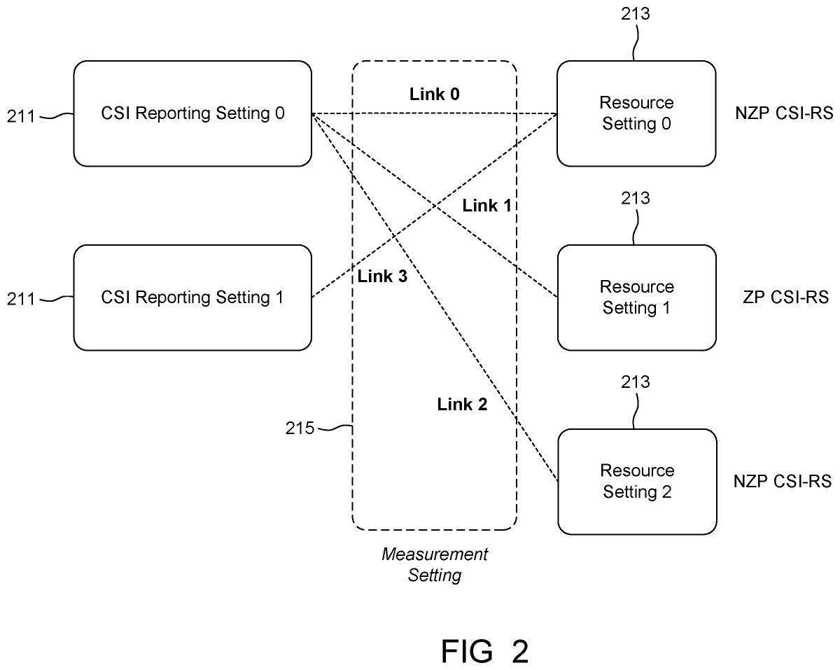

A WTRU may be configured with a CSI configuration that may include one or more CSI reporting settings, resource settings, and/or a link between one or more CSI reporting settings and one or more resource settings. The link may be achieved, for instance, by providing pointers to resource configurations within the CSI reporting settings. FIG. 2 shows an example of a configuration for CSI reporting settings, resource settings, and link.

In a CSI configuration, one or more of the following configuration parameters may be provided: N≥1 CSI reporting settings 211, M≥1 resource settings 213, and a CSI measurement setting 215 that links the N CSI reporting settings 211 with the M resource settings 213. A CSI reporting setting 211 may include at least one of the following: time-domain behavior (e.g., aperiodic or periodic/semi-persistent); frequency-granularity, at least for PMI and CQI; CSI reporting type (e.g., PMI, CQI, RI, CRI, etc.); and, if a PMI is reported, PMI Type (Type I or II) and codebook configuration. A resource setting 213 may include at least one of the following: time-domain behavior (e.g., aperiodic or periodic/semi-persistent); RS type (e.g., for channel measurement or interference measurement); and S≥1 resource set(s) and wherein each resource set may contain K resources, where K is an integer that may be preconfigured. A CSI measurement setting 215 may include a linked pair of at least one of the following: one CSI reporting setting; one resource setting; and, for CQI, a reference transmission scheme setting. For CSI reporting for a component carrier, one or more of the following frequency granularities may be supported: wideband CSI, partial band CSI, and/or sub band CSI.

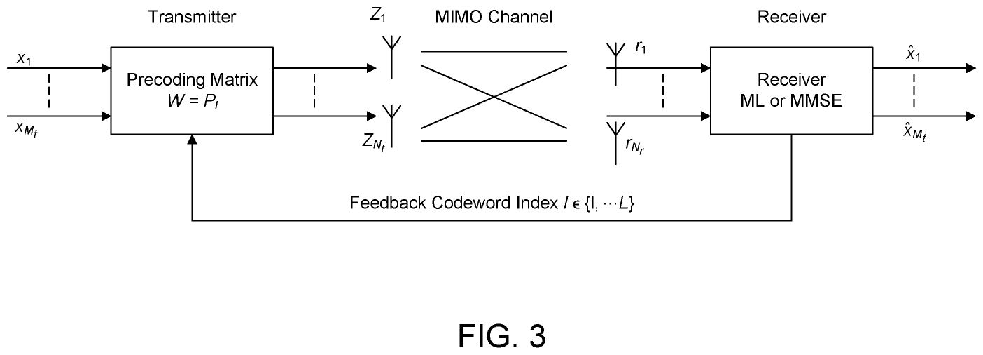

Certain example embodiments may relate to codebook based precoding. FIG. 3 shows a basic concept of codebook-based precoding with feedback information. The feedback information may include a precoding matrix index (PMI) which may be referred to as a codeword index in the codebook as shown in FIG. 3.

As shown in FIG. 3, a codebook includes a set of precoding vectors/matrices for each rank and a number of antenna ports, and each precoding vectors/matrices has its own index so that a receiver may inform the transmitter of a preferred precoding vector/matrix index. Codebook-based precoding may suffer performance degradation due to its finite number of precoding vectors/matrices as compared with non-codebook-based precoding. However, a major advantage of codebook-based precoding is the possibility of lower control signaling/feedback overhead. Table 1 shows an example of a codebook for 2Tx:

TABLE 1
2Tx downlink codebook

| Codebook | Number of rank | |
|---|---|---|
| index | 1 | 2 |
| 0 | $\frac{1}{\sqrt{2}} [ \begin{matrix}1 \\ 1\end{matrix} ]$ | $\frac{1}{\sqrt{2}} [ \begin{matrix}1 & 0 \\ 0 & 1\end{matrix} ]$ |
| 1 | $\frac{1}{\sqrt{2}} [ \begin{matrix}1 \\ - 1\end{matrix} ]$ | $\frac{1}{2} [ \begin{matrix}1 & 1 \\ 1 & - 1\end{matrix} ]$ |
| 2 | $\frac{1}{\sqrt{2}} [ \begin{matrix}1 \\ j\end{matrix} ]$ | $\frac{1}{2} [ \begin{matrix}1 & 1 \\ j & - j\end{matrix} ]$ |
| 3 | $\frac{1}{\sqrt{2}} [ \begin{matrix}1 \\ - j\end{matrix} ]$ | — |

Some example embodiments may include CSI processing criteria. A CSI processing unit (CPU) may be referred to as a minimum CSI processing unit and a WTRU may support one or more CPUs (e.g., N CPUs). A WTRU with N CPUs may estimate N CSI feedback calculations in parallel, wherein N may be a WTRU capability. If a WTRU is requested to estimate more than N CSI feedbacks at the same time, the WTRU may only perform N of the highest priority CSI feedbacks, and the rest may be not estimated.

The starts and ends of a CPU process may be determined based on the CSI report type (e.g., aperiodic, periodic, semi-persistent) as follows. For an aperiodic CSI report, a CPU starts to be occupied from the first OFDM symbol after the PDCCH trigger until the last OFDM symbol of the PUSCH carrying the CSI report. For periodic and semi-persistent CSI report, a CPU starts to be occupied from the first OFDM symbol of one or more associated measurement resources (not earlier than CSI reference resource) until the last OFDM symbol of the CSI report

The number of CPUs occupied may be different based on the CSI measurement types (e.g., beam-based or non-beam based) as follows. For non-beam related reports, K CPUs are occupied when there are K CSI-RS resources in the CSI-RS resource set for channel measurement. For Beam-related reports (e.g., “cri-RSRP” (CSI-RS resource indicator-Reference Signal Received Power, “ssb (synchronization signal block)-Index-RSRP”, or “none”), one CPU is occupied irrespective the number of CSI-RS resource in the CSI-RS resource set for channel measurement due to the CSI computation complexity being low. It is noted that “none” is used for P3 operation or aperiodic Tracking Reference Signal (TRS) transmission. For an aperiodic CSI reporting with a single CSI-RS resource, one CPU is occupied. For a CSI reporting K CSI-RS resources, K CPUs are occupied as the WTRU needs to perform CSI measurement for each CSI-RS resource.

When the number of unoccupied CPUs (Nᵤ) is less than the required number of CPUs (Nᵣ) for CSI reporting, the following WTRU behavior may be used. The WTRU may drop N_r-N_u CSI reporting based on priorities in the case of UCI on PUSCH without data/HARQ (Hybrid Automatic Repeat Request). The WTRU may report dummy information in Nr-Nu CSI reporting based on priorities in other cases to avoid rate-matching handling of PUSCH.

Artificial intelligence may be broadly defined as the behavior exhibited by machines. Such behavior may e.g., mimic cognitive functions to sense, reason, adapt and act.

Machine learning may refer to the types of algorithms that solve a problem based on learning through experience (‘data’), without explicitly being programmed (‘configured set of rules’). Machine learning may be considered a subset of AI. Different machine learning paradigms may be envisioned based on the nature of data or feedback available to the learning algorithm. For example, a supervised learning approach may involve learning a function that maps an input to an output based on labeled training example, wherein each training example may be a pair consisting of input and the corresponding output. For example, an unsupervised learning approach may involve detecting patterns in the data with no pre-existing labels. For example, a reinforcement learning approach may involve performing a sequence of actions in an environment to maximize the cumulative reward. In some embodiments, it is possible to apply machine learning algorithms using a combination or interpolation of the above-mentioned approaches. For example, a semi-supervised learning approach may use a combination of a small amount of labeled data with a large amount of unlabeled data during training. In this regard semi-supervised learning falls between unsupervised learning (with no labeled training data) and supervised learning (with only labeled training data).

Deep learning refers to a class of machine learning algorithms that employ artificial neural networks (specifically Deep Neural Networks (DNNs)) which were loosely inspired from biological systems. DNNs are a special class of machine learning models inspired by the human brain wherein the input is linearly transformed and passed-through non-linear activation function multiple times. DNNs typically comprise multiple layers where each layer comprises a linear transformation and a given non-linear activation functions. DNNs may be trained using the training data via a back-propagation algorithm. Recently, DNNs have shown state-of-the-art performance in a variety of domains, e.g., speech, vision, natural language etc. and for various machine learning settings, such as supervised, un-supervised, and semi-supervised. The term AIML-based methods/processing may refer to realization of behaviors and/or conformance to requirements by learning based on data, without explicit configuration of sequence of steps or actions. Such methods may enable learning complex behaviors that might be difficult to specify and/or implement when using legacy methods.

Machine-to-machine AI/ML transfer learning and inference systems that are connected together via 5G (and 5G+) networks is a promising tool to deal with scenarios where the availability of large datasets may not be practical due to the cost of data collection procedures and the highly dynamic behavior of systems. Sharing of knowledge among diverse learning algorithms can reduce the size of the dataset needed and improve the learning accuracy and rate. However, there are implementation challenges to efficiently and seamlessly deploying and using transfer learning to achieve any gains. One such challenge is the non-existence of performance metrics to measure the success of transfer learning from the source system to the target system. Furthermore, the required bandwidth, security, and privacy level of the transferred knowledge as well as the convergence time to finish the training at the source and the delay to accomplish the transfer from the source WTRU to the target WTRU may be hard to determine.

In this disclosure, it is assumed that there are multiple AI/ML systems available in a low-latency, high-reliability, and high-bandwidth system enabled for machine-to-machine interaction (e.g., via the sidelink interface). The interaction may also be via the network (i.e., using the Uu link). This framework is compatible with the proposed descriptions from 3GPP TR 22.874 [7], whereby AI/ML systems may continuously exchange and share AI/ML model layers in a distributed and/or federated network as determined by the system in response to a change of events, conditions, or emergency situations, to improve some or all of the ML system prediction accuracy. These systems may optimize the AI/ML inference latency by executing different layers on various AI/ML networked systems.

There are two main types of ML model processing/training, namely: (1) using non-real time training, and (2) using real-time training. AI/ML models can be trained and optimized with very large datasets and parameters using extensive computing resources based on specific sets of input training data to achieve the highest accuracy possible in the performance of the ML model. Training is typically done offline over a long period of time, and the resulting trained model may act as a baseline/generic model that a WTRU may take and further train/fine-tune using its local data.

The WTRU may use real-time data for online training of partial or complete AI/ML models. The WTRU may use local data to retrain/improve/fine-tune an ML model it received from the network. The use of real-time training also is applicable for applications where different types of ML systems are connected to exchange part or complete AI/ML model data or parameters to improve prediction accuracy. WTRUs can continuously improve their local ML model based on data gathering from the environment by the WTRU or other sensors. The WTRUs can upload improved model data/parameters periodically to a larger cloud-based network where further processing takes place to further refine the full ML model.

Certain example embodiments may be configured to leverage transfer learning for enhancing Channel State Information processing. An AI/ML capable WTRU (also interchangeably referred to in this disclosure as ML capable WTRU, ML encoder/decoder, ML capable channel estimation decoder or simply WTRU) is a WTRU that is configured with one or more Artificial Intelligence (AI)/Machine Learning (ML) models, also interchangeably referred to in this disclosure as ML model, ML encoder/decoder, CSI model, CSI derivation model, CSI prediction model, CHEST model, CSI model estimator and/or predictor and/or derivator etc. Throughout this document, (model) lifecycle management stages/processes may refer to any one or more of the following: model training/retraining/fine-tuning, model performance monitoring, model selection/activation/deactivation/switching/fallback to legacy, model inference, etc. An AI/ML capable WTRU may be an anchor WTRU and/or a collaborative WTRU. An AI/ML capable WTRU may transition from an anchor WTRU role to a collaborative WTRU role or vice-versa.

An anchor WTRU, in the context of this disclosure (interchangeably referred to as the Model Trainer WTRU or primary WTRU) refers to an AI/ML capable WTRU involved in performing one or more of the following: partial or complete training/retraining of an AI/ML model, receiving configurations from the network on the training parameters of AI/ML models (e.g., performance thresholds determining quality of training to ensure maintenance of QoS when using the ML model), sending of the trained model/trained model parameters in the uplink to the network, hosting of the application function (e.g., AI/ML application) from which a request for training/retraining may be received, sending information related to the training to the network and/or to the collaborative WTRU, and/or sending of the trained model/trained model parameters to the collaborative WTRU(s) via the sidelink interface.

A collaborative WTRU, in the context of this disclosure (interchangeably referred to as the Model User WTRU or secondary WTRU or member WTRU) refers to an AI/ML capable WTRU involved in performing one or more of the following: partial or complete training/retraining of an AI/ML model, receiving configurations from the network on the training parameters of AI/ML models (e.g., performance thresholds determining quality of training to ensure maintenance of QoS when using the ML model), receiving of the trained model/trained model parameters from the network in the downlink and/or directly from the anchor WTRU via the sidelink interface, sending information related to the training/fine-tuning of the model to the network and/or to the anchor WTRU.

A collaborative group (interchangeably referred to as collaborative WTRU group or WTRU group) may comprise one or more WTRU(s), wherein a WTRU that transmits or sends an AI/ML capable model and/or AI/ML model parameters (e.g., in the uplink) may be referred to as the anchor WTRU and a WTRU that receives a trained AI/ML capable model and/or model parameters (e.g., in the downlink) may be referred to as the collaborative WTRU and/or member WTRU. A WTRU may change role, from anchor WTRU to collaborative/member WTRU and/or vice-versa.

An ML-capable WTRU is configured with a first set of ML model(s) that may comprise one or more ML models for CSI derivation/channel estimation/prediction. The models may be among a subset of models pre-approved by the network. The model(s) may have been implemented by the WTRU vendor or pre-downloaded from the network (from the serving gNB or possibly another gNB) or the model may be among a list of pre-defined models as per the standards.

The model(s) configured at the WTRU may be trained either periodically, semi-periodically, or when triggered, either through requests from the network or other triggers (e.g., channel measurements) from the WTRU. The models may have model IDs that may be able to uniquely identify them, assigned by the WTRU and indicated to the network or vice-versa. The model(s) also may have additional descriptive information tagged to them (such as model type, e.g., Recurrent Neural Network (RNN), Deep Neural Network (DNN), Convolutional Neural Network (CNN), etc.)

In one example, the WTRU may train one of the ML models it is configured with until the model conforms to a threshold for a performance metric, which may be set by the network to ensure a certain Quality for the outputs of ML models. The WTRU may then report to the network the completion of training of its ML model, and send the ML model (parameters) in the uplink at the request of the network.

In another example, the WTRU may assess the validity/applicability of each model in the first set of models that it is configured with and may determine that none of the model(s) it is configured with matches its requirements, and the WTRU may determine that it requires a model transfer (e.g., in the downlink).

A second set of ML models may be present at the network. These ML models may be specified in the standards, implemented by the network operator, or pre-downloaded from a server. The models may be gNB-specific or the same set of models may be shared among different gNBs. The second list of models present at the network/gNB may have been trained by WTRU(s) other than the WTRUs with which the ML models will be shared/used, possibly in a similar environment (e.g., similar propagation delay) as the environment in which the models will be shared/used.

In an example, the gNB may send a list of one or more trained models to a WTRU (e.g., through broadcast in a System Information Block (SIB)). The models may have model IDs that uniquely identify them, assigned either by the WTRU that trained them or by the network.

In another example, a WTRU may send assistance information to the network which may include capability information (e.g., the ML model type(s) that the WTRU is configured/compatible with, WTRU antenna configuration, WTRU positioning/location information, bandwidth part that the WTRU is configured with, etc.). The network may perform an initial filtering and send an indication with a list of trained ML models (e.g., model IDs) available at the network corresponding to the WTRU's capabilities as a response to the assistance information sent by the WTRU.

An AIML model may be associated with a model profile. In an embodiment, a WTRU may be configured with an association between an AI/ML model and a model profile. In another embodiment, a WTRU may determine/update the model profile associated with an AI/ML model, for e.g., based on outcome of a training procedure.

According to an embodiment, a model profile may include configuration and/or information about the number of layers (e.g., N1) that are updated out of total number of layers (e.g., N). Once the WTRU receives the deep learning model, it may choose to directly use the pre-trained model or retrain the whole or part of the received model. Post receiving the trained model, the WTRU may establish that the received model is not directly suitable for channel estimation or CSI derivation. Even though the received model may not be suitable for direct deployment, parts of the model may be directly utilized either for the inference or retraining purposes.

According to some example embodiments, a WTRU may be configured to perform training and update a portion of the AI/ML model based on the model profile determined by the WTRU—e.g., number of layers (i.e., N-N1) that are unchanged and a number of layers (i.e., N1) whose weights may be updated as a result of training.

For example, the received deep learning model may have N layers. The low-level features extracted by the first N1 layers may be directly suitable for the WTRU and may not require retraining and hence the weights of these layers may be kept ‘frozen’ for the training process. The remaining N-N1 layers may require retraining by the WTRU and these weights may be updated during the fine-tuning or retraining process at the WTRU based on the data locally available at the WTRU.

The choice of the parameter N1, indicating how many layers may be directly utilized by the WTRU and how many will require re-training may be decided by the WTRU based on channel characteristics computed at the WTRU using the reference symbols (e.g., CSI-RS, DMRS, etc.). The WTRU may provide the parameter N1 to the gNB.

Alternatively, the channel characteristics computed at the WTRU, may also be indicated to the gNB which may then decide that only a part of the model (e.g., the first N1 layers) may be useful for the WTRU and may transmit only that part of the model (e.g., the first N1 layers) to the WTRU.

According to certain example embodiments, a WTRU may be configured to transfer a portion of the AIML model based on the model profile determined by the WTRU—e.g., number of layers (i.e., N1) that are different from baseline model of N layers.

Once the training at the WTRU is completed, the WTRU may transmit an indication that training is complete to the gNB. The gNB may initiate a model transfer request (i.e., send a request to the WTRU to send the model to the gNB. In such a scenario, the WTRU may be required to share the trained model or the trained model parameters and some statistics about the training data conditions with the gNB. In an example, if the WTRU has utilized an existing model received from gNB for the transfer learning process and only a part of the base model received from the gNB was trained (e.g., the last N-N1 layers) whereas the other layers (e.g., the first N1 layers) were kept constant or ‘frozen’, then the WTRU may indicate to the gNB that only a part of the model was retrained. The WTRU may share the weights corresponding to the trained layers (e.g., last N-N1 layers) only.

According to some example embodiments, a model profile may include configuration and/or information about a version associated with the AI/ML model. Each AIML model may be associated with a unique version number. For example, the version number may be configured by the gNB, possibly as a part of model profile. For example, the WTRU may be configured to autonomously assign a version number for an AI/ML model. The WTRU may assign a different version number to different updates to the same AI/ML model, possibly after an update as a result of the training procedure. In an embodiment, the WTRU may be configured to select a version number within a version number space configured by the gNB. In an embodiment, the WTRU may be configured with a version number format that comprises two parts. The first part may carry a WTRU-specific identifier and a second part may be a model-specific identifier.

Particularly, the gNB potentially may have several different versions of the model received from different WTRUs. Thus, these models may need to be appropriately versioned, and it is important to capture the information regarding the data conditions under which they were trained and are expected to perform well.

For many of these deep learning models, the weights associated with the initial layers of the neural network may be the same since many of these networks may have been trained over the same baseline models. Thus, as part of the model versioning, it may be useful to refer to the model version number associated with the baseline model and the number of layers directly reused (‘frozen’ layers) from the baseline model. Since these ‘frozen’ layers have been used without retraining, and are identical to the baseline models, they may not need to be stored explicitly, and only the retrained layers may need to be saved.

According to certain example embodiments, a model profile may include configuration and/or information about a model performance metric associated with the AI/ML model. Each AIML model may be associated with a performance metric. Some examples of model performance metric may include, but are not limited to: NMSE (Normalized Mean Square Error), Cosine Similarity, etc. In one example, the WTRU may receive the performance metric for a model from the gNB, possibly for AIML models downloaded from the gNB. In another example, the WTRU may be configured to determine a performance metric for an AIML model, possibly by measuring AIML model performance over a predefined dataset and/or a dataset collected/observed over a time period.

According to an embodiment, a WTRU may be configured with different levels of model profile wherein each level may refer to the amount of information associated with the model profile

Different levels of model profile may be configured to enable the WTRU to trade off between signaling overhead and the level of exposure of model details. For example, model-specific parameters that can be shared may include model parameters related to data domains and tasks that can be shared: e.g., model weights, partial labeled datasets, algorithm (e.g., parameters of minimization/optimization function)). When transferring the models between the WTRU and the gNB or between WTRUs, different levels of information exchange may be configured, for example.

Level 1: This is the most basic level of information exchange. This may include at least one of: the weights associated with the trained model, the version number of the baseline model used (if any), or very basic channel characteristics (e.g., doppler, delay spread, Signal to Noise Ratio (SNR)) under which the model was trained. The model shared at this level may even be a compressed version of the actual model with quantized weights. The model compression and quantization may marginally affect the accuracy of the model.

Level 2: At this level, a higher degree of information may be provided. In addition to Level 1 information, the WTRU also may share more detailed information about the channel characteristics or may also share some representative data samples used for model training. The models shared at this level may either be uncompressed with floating point weights or may have a lower degree of compression and quantization as compared to Level 1.

Level 3: This is the highest level of information that may be provided by the WTRU. In this level, in addition to the information shared in Level 2, the WTRU may share at least one of: a larger number of training examples, the training parameters used for training (like the optimizer used, learning rates, the cost function, data augmentation methods used (if any), regularization used (if any), etc.). Beyond that, the models shared at this level may be either uncompressed and unquantized or may have a lower degree of compression or quantization as compared to Level 2.

The ML model validity relies on some conditions, i.e., validity conditions, that determine for how long and/or under what conditions the ML model is valid. These conditions may be sent in the uplink alongside model transfer in the uplink by the anchor WTRU. The WTRU may receive (e.g., in the downlink or from the network/gNB) conditions on the validity of a model, possibly alongside the model itself. Examples of parameters that may determine the validity of the model and that may, completely or partially, be sent/received alongside the model in the downlink or alongside model transfer in the uplink include any one or more of the following: data distributions or data distribution statistics, measurements (e.g., channel measurements) that were used to train the AI/ML model (e.g., channel coherence bandwidth, channel coherence time, Doppler spread, delay spread, SINR, etc.), static information about the AI/ML model, information about model parameters as described in the foregoing, information about model performance (e.g., thresholds or performance thresholds, history/performance of the model at the WTRU, training frequency of the model at the WTRU.

Data distributions or data distribution statistics may include complete datasets or partial datasets. It may include training dataset(s) and/or validation dataset(s) and/or test dataset(s). It may include any type of dataset (e.g., numerical, bivariate, multivariate, correlation, etc.).

Measurements (e.g., channel measurements) may include measurements that were used to train the AI/ML model (e.g., channel coherence bandwidth, channel coherence time, Doppler spread, delay spread, SINR, etc.). In an example, an ML model may output (e.g., only output) reasonable estimates for channel estimation/prediction/CSI derivation within a given SNR range. Outside of that range, the estimate is outside the margin of error (which may be determined, e.g., when computing the NMSE between the ML model output and the traditional CSI computation using CSI-RS). The measurements may include channel coherence time measured by the anchor WTRU. In an example, the WTRU may determine how fast-varying or slow-varying the channel is based on the measurement of the channel coherence time, at the same time the ML model was/is being trained. The WTRU may either report the raw channel coherence time value to the network alongside the model being sent in the uplink or it may use the channel coherence time to determine a validity period over which the anchor WTRU may assume the model to be valid for in the future. As a result of being a universal metric characterizing the fading characteristics of the channel used in the training of the model, the channel coherence time may be a good measure of how good the model is and/or how long the network/another WTRU may be able to use the ML model. This may be especially true for a neighboring WTRU in a similar environment that may be experiencing similar propagation delay and channel conditions.

Static information about the model (e.g., model size, overhead associated with the model, latency for the model to output a result) is another example parameter that may factor in the decision of whether the model is suitable for use. The parameters (e.g., model size, overhead, latency of model) may be reported as raw metrics. Alternately, other parameters that implicitly/explicitly provide the information may be determined by the WTRU or the network. In an example, the WTRU may report the size of the ML model (e.g., in Mbytes, Mbits, or Kbytes, etc.). In another example, the WTRU may report the bandwidth required to download the model, which may implicitly tell the network about the model size. In another example, the WTRU may report the size of the ML model (e.g., in Mbytes, Mbits, or Kbytes, etc.) leaving it to the network to determine the required bandwidth to download the model. In an example, the WTRU may measure training metrics of the model and report them back to the network (e.g., time to train, number of iterations, amount of data required). In another example, the network may send a request to the anchor WTRU for it to train its ML model. The network may measure the time of sending the request to the time of receiving a trained ML model and determine the total latency of training and sending the model (including model processing/training latency and communication latency on the Uu link of the anchor WTRU). Based on knowledge of the communication delay, the network may determine the training time. Granularity of maintaining/reporting of model parameters may vary. In an example, the WTRU may determine and report to the network the time or number of resources it took to train the complete model. In another example, the WTRU may determine and report to the network the time or number of resources it took to train some layers of the model, and report the number of layers trained alongside the training time. In an example, on receipt of a request for model transfer from the network, the anchor WTRU may send the model (parameters) to the network. The network may determine the total communication latency of the link based on the knowledge of the round trip time between the WTRU and the gNB.

In an example, the WTRU may determine the validity of the model based on its performance, e.g., during testing phase. In an example, the WTRU may know how well the ML model has performed during the testing phase and may determine the validity of the model (e.g., how long the model may be valid for based on its performance.

In an example, the WTRU may determine the validity of the ML model based on the training frequency of the model. In an example, if the WTRU knows that the ML model has required training/retraining, on average, every X seconds, it may report to the network a validity of X ms associated with the ML model.

Whenever the anchor WTRU sends a model in the uplink, it may also send validity information associated with the model. The validity information may be based on the factors listed above (e.g., channel coherence time measured by the anchor WTRU, training frequency of the ML model, etc.). In an example, this information may be sent in the form of a validity timer sent alongside the model, or in the form of conditions (e.g., ML model may be downloaded only if enough bandwidth is available based on model size) or in the form of an applicable range (e.g., ML model valid for specific SNR range).

Whenever the network sends a model in the downlink to a member WTRU, it may also send the associated validity information so that the member WTRU knows for how long the model is valid for. In an example, an ML model sent in the downlink with a validity timer of, e.g., Y ms, may tell the member WTRU that the ML model may only give output within the margin of error (e.g., NMSE<Threshold T) for Y ms. The member WTRU may determine for how long to use the model based on the validity information, and what its back-up options may be. A member WTRU may apply or start the validity timer upon reception of the ML model or upon first using the ML model. The WTRU may determine a model is not valid upon expiration of the validity timer. A validity timer may be defined as a number of slots or resources or transmission resources/occasions. In one example, the member WTRU may send a request to the gNB to increase the frequency of the CSI-RS after Y ms. In another example, the member WTRU may send a request to the gNB for another ML model (parameters) in the downlink

The validity information may also be sent without the model, in the uplink, downlink, and/or over the sidelink interface. In such cases, the validity information may serve to provide information about the AIML model validity beforehand to avoid the overhead of sending the model first and then determining its validity.

In some examples, there may be an initial exchange of information. For example, to configure a WTRU with a specific AIML model (e.g., CNN, DNN) for channel estimation and prediction, the gNB may require information about the capabilities of the WTRU as well as other information that enables the gNB to configure the WTRU with specific information for the estimation/prediction process (e.g., CNN, DNN, RNN weights).

The WTRU may send the capabilities information for model assistance (hereinafter sometimes referred to as model assistance information), such as the model(s) the WTRU may be configured with (e.g., DNN, CNN, RNN), WTRU antenna configurations, WTRU positioning/location/orientation information, WTRU bandwidth part that WTRU is operating on, and WTRU CSI statistics.

The WTRU may send the model assistance information periodically or aperiodically using Uplink Control Information (UCI), possibly depending on the variations in the CSI distribution observed. Sending of the model assistance information may also be event-triggered (e.g., a large variation in CSI distribution observed may trigger the WTRU to send/resend model assistance information).

The gNB may send the data distribution statistics on all the AIML models (e.g., CNN, DNN, RNN) available at the gNB, with corresponding threshold(s) of convergence. In other words, the gNB may convey the information of all available AIML models (e.g., DNN, CNN, RNN) and the parameters each AIML model is trained for (e.g., the channel estimation/prediction error threshold, convergence rate, etc.). A WTRU may receive the set of information associated with AIML models available at its gNB. The set of information associated with AIML models may be received via dedicated transmission (e.g., PDSCH), via RRC, or via broadcast information (e.g. PBCH, SIB, SSB).

The gNB may also send CSI-RS samples to the WTRU to observe the channel distribution characteristics and select the AIML model specific to the observed channel distribution characteristics. A WTRU may be configured with CSI-RS to perform and report channel distribution measurements.

In an example, if the data distribution statistics/model profile of the gNB do not match with the observed channel distribution characteristics/model profile at the WTRU, the WTRU may send an indication to the gNB saying that no match has been found and request online training

In an example, depending on the AIML model assistance information sent to the gNB by the WTRU, the gNB may select a specific AIML model that is close to or matches the assistance information the gNB received from the WTRU. A WTRU may receive multiple models and may select an appropriate one as a function of a measurement or capability.

The gNB may then configure the WTRU with the AIML model that is best suitable for the WTRU based on the assistance information (e.g., channel conditions), where the WTRU may employ the AIML model using the configured model and perform channel estimation and prediction.

In an example, if the WTRU data distribution characteristics/statistics match one of the data distribution models available at the gNB, the WTRU may indicate the AIML matching information to the gNB. In response, the gNB may send the AIML model parameters (e.g., model weights) of the relevant model to the WTRU.

In an example, after the model weights have been downloaded/deployed at a WTRU, the WTRU may choose to update the weights to fine tune based on the channel conditions specific to the WTRU.

A WTRU may be provided with one or more AIML models. The WTRU may receive or download an AIML model from a gNB or another WTRU. A WTRU may determine an AIML model based on training performed by the WTRU or by another network node (e.g., gNB or another WTRU). A WTRU may determine a model from a combination of a first model (e.g., possibly obtained from another network node) and training performed by the WTRU. For example, a WTRU may obtain a first/coarse AIML model and the WTRU may refine the model with training. A WTRU may determine an AIML model from a combination of two or more AIML models.

A WTRU may determine whether an AIML model is applicable to at least one of its functions. For example, a WTRU may use or require an AIML model to perform at least one of channel estimation, channel prediction, CSI measurements, positioning, beam failure detection/recovery, mobility, Radio Link Monitoring (RLM), or unlicensed channel monitoring/assessment.

A WTRU may determine whether an AIML model is suitable to be used for at least one of the applicable functions. Suitability may be defined as the model achieves the required performance for the applicable function. Suitability may be defined as a set of parameters associated with the AIML model that are applicable to the WTRU or the function of the WTRU. Suitability (or required performance) may be configured per function. Suitability may be determined from at least one criterion being achieved. The WTRU may be configured with the at least one criterion.

The WTRU may determine the suitability of an AIML model based on at least one of: WTRU capabilities, model type, WTRU traffic type, measurements, comparison with legacy function, whether a WTRU is part of a group to which an AIML model is associated with, and/or hysteresis information.

For example, WTRU capabilities may include at least one of: antenna configuration, numerology (e.g., SCS, waveform), number of Tx/Rx chains, whether the WTRU supports Frequency Division Duplexing (FDD)/Time-Division Duplexing (TDD)/Cross Division Duplexing (XDD)/full-duplex/half-duplex, number of panels. The WTRU may determine an AIML model is suitable if it is applicable to at least one of its capabilities.

With respect to model type, for example, a WTRU may support at least one of the following model types: DNN, Untrained Neural Network (UNN), CNN, RNN, or autoencoder. A WTRU may determine an AIML model is suitable if it uses a model type that the WTRU supports.

A WTRU may determine an AIML model is suitable if it is applicable to the WTRU's traffic type. The traffic type may be defined as or may include at least one of: periodic/aperiodic, burst start/end/duration, reliability, latency, throughput.

With respect to measurements, for example, a WTRU may be configured with resources on which to perform at least one measurement. The WTRU may compare the at least one measurement to at least one threshold. The at least one threshold may be configurable. If the at least one measurement is greater or less than the at least one threshold, the WTRU may determine that a model is suitable. A model may be associated with at least one measurement threshold. A WTRU function may be associated with at least one measurement threshold. The measurement may include and/or relate to at least one of: position, velocity, and/or direction of mobility; L1 or L3 measurements such as Reference Signal Received Power (RSRP), Received Signal Strength Indicator (RSSI), Reference Signal Received Quality (RSRQ), Signal to Interference and Noise Ratio (SINR), Channel Occupancy (CO), Rank Indicator (RI), Channel Quality Index (CQI), Pre-coding Matrix Indicator (PMI), Layer Indicator (LI); interference measurement; Doppler, Doppler spread, delay spread, number of multipaths; coherence time, coherence bandwidth; beam direction, beamwidth, set of beams (e.g., elements in the set of the cardinality of the set); energy detection; rate of successful channel access attempts (for example, the WTRU may maintain the number or percentage of successful Listen-Before-Talk (LBT) attempts over a period of time. The period of time may be dynamically determined (e.g., sliding window)); rate of NACKs (for example, a WTRU may maintain a measurement of the number or percentage of NACKs over a period of time. The period of time may be dynamically determined (e.g., sliding window)); path loss; whether the path is line of sight or non-line of sight; throughput; BLER; and/or latency.

With respect to performing a comparison with legacy function, for example, the WTRU may compare the performance of the AIML model on a function with the expected performance of using a baseline (e.g., non-AIML) method to perform the function. A WTRU may determine a rate of error events from using the AIML model. An error event may be determined when the difference between the output of the AIML model and a baseline method is greater than or less than a threshold value. The WTRU may determine suitability of the AIML model if the rate of error events is greater than or less than a threshold. The WTRU may determine suitability of the AIML model if the difference between the output of the AIML model and the baseline model is greater than or less than a threshold.

In an example, a WTRU may determine the suitability of an AIML model based on whether a WTRU is part of a group to which an AIML model is associated with. For example, an AIML model may be associated with a group of WTRUs and whether the WTRU is part of the group may enable the WTRU to determine if the AIML model is suitable or not.

Regarding hysteresis, for example, a WTRU may determine if an AIML model is suitable as a function of whether the WTRU has recently determined that the AIML model was not suitable. For example, if a WTRU determines that an AIML is not suitable, it may not reuse or re-test the model for suitability for a certain period of time (e.g., fixed, predetermined, variable). This may ensure a WTRU does not repeatedly ping-pong between models.

A WTRU may send an indication to a gNB or to another WTRU when it determines that a model is not suitable. A WTRU may request a new model, an update to the model, and/or resources to retrain a model or train a new model when the WTRU determines that a model is not suitable.

Certain embodiments may include triggers to check for model suitability. For example, prior to using an AIML model, a WTRU may determine whether the model is suitable, where suitability may be as described herein. A WTRU may receive a command from the gNB or another WTRU to check whether an AIML model is suitable for at least one WTRU function. A WTRU may determine to test an AIML model for suitability when it receives at least one new AIML model.

In another embodiment, a WTRU may be triggered to check or recheck for the suitability of an AIML model as a function of at least one of: Time period (e.g., the WTRU may be configured with periodic time instances to check for AIML model suitability. In another example, a WTRU may be triggered with semi-persistent time instances to check for AIML model suitability; configuration, activation and/or deactivation of a cell; change in channel conditions (e.g., where the channel conditions may include at least one of: doppler, doppler spread, delay spread, Line-of-Sight (LOS)-to-Non-Line-of-Sight (NLOS), NLOS-to-LOS, path loss, coherence time, coherence bandwidth, channel type); change in L1 or L3 measurement value (for example, the WTRU may be triggered to check for the suitability of an AIML model if at least one of: RSRP, RSRQ, SINR, RSSI, CO, RI, CQI, PMI, LI changes by more than a threshold value); when the set of best subbands changes; change in Radio Resource Control (RRC) state (IDLE, CONNECTED, INACTIVE); discontinuous Reception (DRX) configuration or change in DRX configuration; RRC (re) configuration; PHY (e.g., DCI) or MAC layer (e.g., MAC CE) indication; change of BWP (for example, if the WTRU changes BWP due to timer expiration, the WTRU may check the suitability of the AIML model); change of beam or beam pair (for example, when the set of best beams changes, the WTRU may check the suitability of the AIML model); detection of Beam Failure; change of transmission mode; RLM/RLF (Radio Link Failure); change of position (e.g., translation or orientational. For example, the WTRU may be triggered to check AIML model suitability if the position changes by more than a threshold value); change of traffic type (for example, the WTRU may be triggered to check AIML model suitability if the priority of the traffic changes0; change in buffer status (for example, the WTRU may be triggered to check AIML model suitability if the buffer status is above or below a threshold value); when triggered to transmit a Scheduling Request (SR), or Uplink Reference Signal (UL RS) (e.g., Sounding Reference Signal (SRS)) or Configured Grant (CG) transmission; when the difference between the performance of an AIML model and that of a baseline method is greater or less than a threshold value; difference between historical values and ML model output become greater than or less than a threshold; when a WTRU determines that a model needs retraining or refining; HARQ-ACK (Hybrid Automatic Repeat Request) outcome or Block Error Rate (BLER) (for example, the WTRU may be triggered to check the suitability of an AIML model when the rate of NACKs exceeds a threshold or when the BLER is less than or greater than a threshold); traffic performance (for example, the WTRU may be triggered to check the suitability of an AIML model when at least one of throughput, reliability, and latency is greater than or less than a threshold); reception of a new or updated AIML model; reception of a SideLink (SL) broadcast or DL broadcast of new or updated models; AIML failure detection (for example, a WTRU may determine and count events when an AIML model failed. Failure may be determined in a manner similar to the triggers discussed herein (e.g., based on a comparison with a baseline model). If the failure count exceeds a configurable value, the WTRU may declare AIML failure detection or may be triggered to check AIML model suitability. The failure count may be reset when a failure timer expires. A failure timer may be restarted when a failure event is determined. In another embodiment, the WTRU may start a timer upon determining N (e.g., N consecutive) failure events (where N may be configurable). If the WTRU does not determine M success event(s) while the timer is running, the WTRU may declare AIML failure detection or the WTRU may be triggered to check AIML model suitability); when the WTRU is configured with or receives model retraining resources (for example, the WTRU may be configured with periodic bursts of model retraining resources. Prior to using the resources to retrain an AIML model, the WTRU may check the suitability of a model. The WTRU may (e.g., may only) retrain a model if the model is deemed suitable or not suitable); when the WTRU changes WTRU groups (e.g., A WTRU may be assigned to or determine a WTRU group. Such a group may share models. The WTRU may be triggered to check the suitability of an AIML model when the WTRU changes groups); when there is a change of the source of an AIML model (for example, an AIML model may be trained by a first node (WTRU or gNB) and may be updated by a second node (WTRU or gNB). The WTRU may be triggered to check the suitability of the AIML model when the training or retraining node associated with a model changes); and/or upon completion of training a new AIML model (for example, the WTRU may check the suitability of a first AIML model upon completion of the training of that or a second AIML model).

Triggers, parameters thereof, and/or thresholds to check for the suitability of an AIML model may depend on whether the WTRU trained and shared the model or the model was trained at another node (WTRU or gNB) and shared with this WTRU. For example, a WTRU may be configured with a first set of triggers or thresholds associated with models trained and shared by the WTRU and a second set of triggers and thresholds associated with models trained elsewhere shared with the WTRU. In another embodiment, each model may be configured with a set of triggers or thresholds. In yet another embodiment, the set of triggers or thresholds may depend on the function for which the AIML may be used.

The triggers discussed above may be reused as triggers for the WTRU to request a new model, an update to a model, and/or resources to retrain a model or train a new model.

Certain embodiments may provide triggers for training and/or retraining. The WTRU may perform channel measurements, e.g., channel coherence time, channel coherence bandwidth, SNR, Doppler spread, etc. Changes in the measured channel conditions may trigger the WTRU to assess the performance of the ML model.

In an exemplary scenario, if the WTRU measures a change in the channel coherence time, it may send an indication to the gNB to report the change. The WTRU may be configured to report the channel coherence time periodically and/or when prompted by the gNB (e.g., via DCI) and/or when it exceeds a corresponding pre-configured threshold. Any change or a change beyond a pre-configured threshold in the channel coherence time may lead the WTRU to trigger training/retraining of the ML model.

A decrease in the channel coherence time may signify the channel changing from a slow-fading to a fast-fading channel. As a result, the WTRU may determine to retrain the model following a decrease in channel coherence time larger than a threshold, which may be configured by the WTRU or the network. The updated training frequency may apply for a pre-determined time window or indefinitely until another event is triggered, e.g., until the WTRU detects/measures an increase in the channel coherence time.

In another exemplary scenario, a small value of the coherence time (i.e., below a preconfigured threshold set by either the WTRU or gNB) may be indicative of a fast-fading channel, implicitly indicating to the WTRU that measurements of additional metrics (e.g., SNR) may be required. The WTRU may report the additional measurements to the gNB either standalone or by including them as part of the CSI feedback report (e.g., CQI, SNR, etc.).

ACK/NACK statistics measured by the WTRU may be indicative of the performance of the ML-based CHEST or CSI derivation model. For example, if the WTRU sends several consecutive NACKs to the gNB, the gNB may send a request to the WTRU to re-assess the performance of the CSI ML model. The number of consecutive NACKS that would trigger training/retraining of the ML model may be configured by the gNB. The gNB may send a request for training/retraining of the ML model at the WTRU. In an example, the WTRU may measure and keep track of ACK/NACK statistics over a time window. If the number/percentage of NACK responses recorded over that window exceeds a pre-configured threshold, the WTRU may re-assess the performance of the ML model, e.g., through computation of the NMSE or cosine similarity.

The WTRU may start a counter/timer every time it completes the training of the CSI ML model. Expiry of the counter/timer may trigger the WTRU to re-train the model. The length of time set by the timer may be measured/recorded in any of the following units: time slots, symbol duration, SFN, and seconds/milliseconds. The counter may be measured in number of symbols. The length of the timer/counter may be pre-configured by the WTRU and indicated to the gNB, or vice-versa. The gNB may send a message to the WTRU to request a change in the length of the counter/timer. In an exemplary scenario, the gNB may register poor uplink channel conditions from CSI reports from the WTRU. The gNB may send a request to the WTRU to decrease the length of the timer/counter to trigger the training/retraining of the ML model.

In cases where computation of the error as described below in Section 4.7 exceed a pre-configured threshold, the WTRU may trigger re-training of the ML model. For example, if NMSE>Threshold T1 and/or if Cosine similarity<Threshold T2, the WTRU may trigger training/re-training of the ML model. The network may also have thresholds corresponding to the performance metrics of the ML-capable WTRUs. In an example, if the WTRU reports the computed NMSE and/or Cosine similarity to the gNB, and the error performance metrics are below the corresponding thresholds at the gNB, the gNB may send an indication to the WTRU to trigger training/re-training of the CSI ML model.

In an example, the WTRU may be configured to report the channel coherence time periodically to the gNB or when prompted by the gNB through an indication sent to the WTRU (e.g., in DCI). There may also be a semi-periodic configuration whereby the WTRU reports the channel coherence time to the gNB with a periodicity set by the gNB as well as when prompted by the gNB and/or when the WTRU measures a large change in the channel coherence time. In an example, there may be configuration of a channel coherence time threshold at the WTRU. Exceeding of the channel coherence time threshold may trigger the WTRU to report of the coherence time to the gNB and/or training/retraining of the ML model at the WTRU. Similarly, thresholds for other channel measurements may also be configured. In an example, if the SNR measured by the WTRU is below the corresponding pre-configured threshold and/or the BLER is above a corresponding pre-configured threshold, the WTRU may trigger training/re-training of the channel estimation model.

In an example, the WTRU may receive explicit requests from the network to train. With the knowledge of the state of the ML models for other ML capable WTRUs in proximity, the network may determine that a particular WTRU may need to refine/retrain its ML model before sending it in the uplink. An exemplary scenario may be when the WTRU is the only WTRU with a ML model that can train with a minimum RS overhead in a stringent time window compared to ML models of neighboring WTRU(s) which may require more CSI-RS to train and/or may take a longer time to train.

In an example, the WTRU may receive a request for training/retraining directly from a neighboring WTRU via the sidelink interface. The WTRU may have received an indication that it has been selected as the basis for transfer learning by the network, which may have been accompanied by the WTRU ID(s) of the neighboring WTRU(s) likely to request a model transfer. The WTRU may receive a request for model transfer which may be preceded by a request for training/refining of the ML model.

The WTRU may use the traditional channel estimation (CHEST) or CSI reporting framework as a reference to assess the output of the ML model and/or calibrate/re-calibrate the neural network. The WTRU may compute the difference/discrepancy/error between the output of the CSI estimation model and the result of the traditional CHEST or CSI reporting framework. The difference/discrepancy/error may be computed through: (i) NMSE and/or (ii) Cosine Similarity.

The Normalized Mean Squared Error (NMSE) may be used as the performance assessment of the ML model whereby the accuracy of the ML model may be inversely proportional to the NMSE value computed at the WTRU. The WTRU may quantify the normalized MSE (NMSE) as shown in the Equation below:

$$NMSE = E ( \frac{{‖ H - \hat{H} ‖}_{2}^{2}}{{‖ H ‖}_{2}^{2}} )$$

where H: CSI channel matrix from traditional channel estimation;
Ĥ: Output of ML enabled decoder; and
E: the expectation (statistical mean).

The cosine similarity measures the similarity between the reference channel matrix and the output of the ML decoder. The WTRU may compute the cosine similarity p as shown in the Equation below:

$$ρ = E \{ \frac{1}{{N}_{c}} {\sum }_{n = 1}^{{N}_{c}} \frac{\vert {h}_{n} {\tilde{h}}_{n}^{H} \vert}{{‖ {h}_{n} ‖}_{2} {‖ {\tilde{h}}_{n} ‖}_{2}} \}$$

where
\tilde{h}ₙ: reconstructed channel vector at the nth subcarrier at the output of the ML decoder; and
N_{c}: the number of subcarriers (or frequency domain samples of the channel matrix.

The NMSE or Cosine similarity is used to quantify the reconstruction performance. The quantified result of the difference/discrepancy/error which may be computed by the WTRU is assessed against a pre-configured threshold. In an exemplary scenario, if NMSE computed by the WTRU<Threshold T1, the WTRU may report to the gNB that the performance of the ML channel estimator is adequate and the WTRU may not trigger re-measurements/re-computation of the NMSE, e.g., for a certain time period.

Similarly, if, in an example, the cosine similarity computed by the WTRU, p, is above a pre-configured threshold, the WTRU may report to the gNB that the performance of the CSI model estimator/predictor/derivator is good or valid or suitable and the WTRU may not trigger re-computation of p for a certain sub-carrier for a certain time period. Conversely, if the cosine similarity computed by the WTRU, p, is below a certain threshold, the WTRU may report the value of the cosine similarity to the gNB, which may send a request for re-training of the model (or the WTRU may trigger re-measurements of the cosine similarity. The aforementioned thresholds may be pre-configured by the WTRU and indicated to/approved by the gNB. The threshold alternatively may be configured by the gNB and shared with the WTRU during initial configuration (e.g., during RRC).

The WTRU may perform additional channel measurements, e.g., channel coherence time, channel coherence bandwidth, SNR, Doppler spread, etc. Changes in measured channel conditions may trigger changes in the thresholds. In an example, if the WTRU measures a decrease in the channel coherence time, it may report the change to the gNB. The gNB may trigger a change in the pre-configured threshold(s) to accommodate the dynamic change in channel conditions.

The WTRU may be configured with multiple thresholds (e.g., T1, T2, T3, . . . , TN) by the gNB for the measurement of one or more performance metric(s). For example, the gNB may configure one or more threshold values, which, when exceeded, may trigger the WTRU to compute the NMSE between the traditional channel estimation and the output of the ML decoder. Each threshold value may be associated with a specific parameter, and the WTRU may decide the threshold to use depending on its measurement of the parameter. In an example, one threshold (e.g., T1) may correspond to a certain SNR range such that, if the SNR is outside of the range, the WTRU may have to use a different threshold (e.g., T2) corresponding to the new measured SNR. The error/discrepancy/difference (e.g., NMSE or cosine similarity) exceeding a final threshold TN may trigger the WTRU to re-train the ML model.

A WTRU may be configured with a first set of reference signals (e.g., CSI-RS) on which to perform channel estimation and compute the CSI estimates. The configuration of the first set of reference signals to compute CSI estimates may be high density and short periodicity or it may be the same configuration for a non-ML capable WTRU. Following computation of the error (e.g., NMSE or cosine similarity), the WTRU may request a change in the periodicity and/or density of the configuration of the reference signals, possibly as a result of the value of the error. In an example, a large error may trigger an anchor WTRU to train/retrain its model. This may be the case especially if the anchor WTRU has knowledge that no trained ML model available at the network at that given time matches its requirements (e.g., based on the data distribution statistics). In another example, a large error computed by a member WTRU may trigger the member WTRU to request for a model transfer in the downlink.

The result of determination of the CSI estimation error may be training/retraining of the AIML model and/or redetermination of model suitability based on any of the parameters discussed above and/or requesting for a model parameter transfer from the gNB.

Certain embodiments may provide a procedure for model upload (e.g., model in UL). For example, an ML-capable WTRU may be configured with a first set of ML models for channel estimation/prediction/CSI compression. The ML model(s) may already be implemented/loaded in the WTRU. Alternatively, the ML models in the first set of models may be downloaded from the gNB, for example, after the WTRU reports the WTRUCapabilityInformation to the gNB. The ML models may have an associated unique identifier (model ID), a model profile (for example, the model profile may describe configuration information, number of layers), model parameters (including input and output size), and data distribution statistics.

In certain embodiments, a WTRU may report assistance information and/or capabilities of the first set of ML models. For example, the WTRU reports to the gNB the capabilities of the ML models it is configured with (e.g., in the first set of models); the WTRU may also report the assistance information related to the configured first set of ML models. For example, the WTRU may report the assistance information to enable the gNB to determine an anchor WTRU for the model transfer, and/or to update its second set of models.

The assistance information for the configured ML models in the first set of models may include one or more of the following: Model type (e.g., RNN, DNN, CNN and the like), Model ID, Model profile, Model parameters including model size, Data distribution statistics (e.g., of the data the model was trained on), WTRU antenna configuration, WTRU positioning/location information, and/or a metric for the model performance (e.g., NMSE).

The WTRU may report the assistance information to the gNB when it detects a change in the operating conditions, for example: when the WTRU detects a change in the channel statistics relative to the statistics of the model training dataset (e.g., this may include change in Doppler spread, delay spread, angular spread, SNR, etc.), when the WTRU detects a significant change in its location and/or orientation, and/or Upon changes of the BWP.

According to some embodiments, a WTRU may receive information on the second set of ML models available at the gNB. For example, the WTRU receives an indication of the ML models in the second set of models available at the gNB. The WTRU may receive the indication, for example, after it reports the assistance information and/or capabilities of the first set of ML models. In another example, the indication may be broadcast in a SIB.

The indication on the second set of ML models available at the gNB may include one or more of the following: Model type (e.g., RNN, DNN, CNN), Model ID, Model profile, Model parameters, including model size, Data distribution statistics (e.g., of the data the model was trained on, which may include Doppler spread, delay spread, SNR, channel coherence time and the like), Number of Rx antennas, and/or a metric for the model performance (e.g., NMSE), and a threshold for model convergence.

In some embodiments, a WTRU may use configured CSI-RS transmissions to measure channel statistics (e.g., to evaluate model suitability). For example, the WTRU may use the configured CSI-RS transmissions to perform traditional channel estimation and determine channel statistics, such as Doppler spread, delay spread, SNR, channel coherence time, and the like.

The WTRU may compare the measured channel conditions to the data distribution statistics received from the gNB for the ML models in the second set of models, for example, to determine if any of the ML models in the second set of models may be used for the current channel conditions.

The WTRU may determine that no ML model from the second set of models fits its requirements, for example, when the measured channel statistics do not match any of the model profiles in the second set of models, or when the parameters (e.g., number of WTRU antennas) do not match.

When the WTRU determines that no ML models from the second set of models fits its requirements, the WTRU may send an indication to the gNB that no ML model fits. The WTRU may implicitly indicate to the gNB that it will train its ML model. In another example, the WTRU may explicitly signal to the gNB that it is entering the model training state.

The WTRU may report to the gNB the specific failure condition, for example, that the current measured SNR is out of the range of all ML models in the second set.

When the WTRU enters the model training state, the WTRU updates the weights of the ML model, for example, using CSI-RS transmissions for on-line training. The WTRU may compute the error (e.g., the NMSE or the cosine similarity) between the ML-based CSI estimate and the traditional CSI estimate. The WTRU may continue the on-line training (e.g., run additional iterations) while the error is larger than a configured threshold.

When the error becomes smaller than a configured threshold, the WTRU may indicate to the gNB the completion of the ML model parameter update. The WTRU may also report the assistance information, for example, the channel statistics measured during the model retraining.

When the WTRU determines an applicable ML model from the second set of models, the WTRU may indicate to the gNB information related to the preferred model. The indication may include one or more of the following: Model ID, Model type (e.g., RNN, DNN, CNN), Model profile, Model size, and/or Data distribution statistics.

The WTRU may send a request to the gNB to download the preferred ML model from the second set.

Certain embodiments may include WTRU triggers to transfer and/or upload the ML model. For example, when the WTRU retrains its model and the error becomes smaller than a configured threshold, the WTRU may indicate to the gNB the completion of the ML model parameter update. The WTRU may also report the assistance information, for example, the channel statistics measured during the model retraining. The WTRU may request an UL grant to transfer its trained model to the gNB.

In an example, the WTRU may receive an ML model parameter request from the gNB, for example, after completion of the WTRU reported model retraining. Upon receiving the ML model parameter request from the gNB, the WTRU may transfer the model parameters to the gNB. The WTRU may also report assistance information for the trained model, such as channel conditions (Doppler, delay spread, angular spread, SNR, etc.).

The gNB may select the WTRU as the anchor for transfer learning, for example, when it determines that the WTRU has a trained model (e.g., best trained model in a cluster of neighboring WTRUs that share similar channel conditions). When selected as the anchor WTRU for transfer learning, the WTRU may receive a configuration indication from the gNB that it was selected as the basis for transfer learning (i.e., that it was designated as the anchor WTRU for a group of WTRUs). The WTRU may freeze the updates of the first layers of the model. The WTRU may also expect to receive a model transfer request, e.g., in UL on Uu, or directly from another WTRU via the sidelink.

The following are example embodiments of processes for training and sharing ML models in accordance with the principles discussed herein.

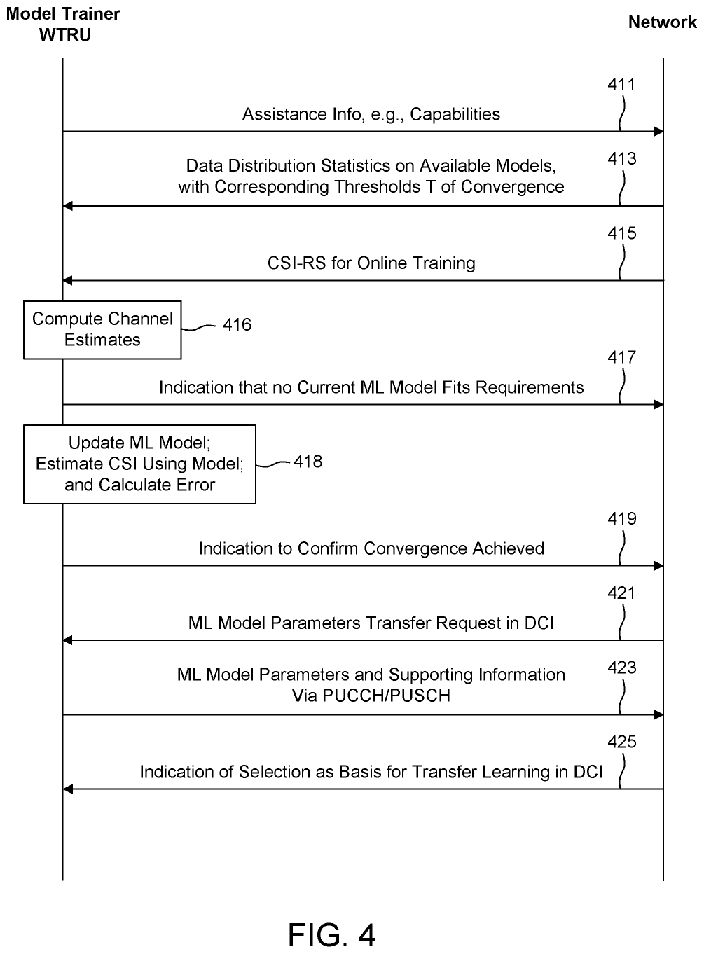

FIG. 4 is a signal flow diagram illustrating an example process for transferring a model from a model trainer or an anchor WTRU to a user WTRU (e.g. model transfer in the UL), in accordance with an embodiment. Initially, an ML-capable WTRU is configured with a first set of ML models for channel estimation.

The models may already be implemented by the WTRU vendor, pre-downloaded from the network (possibly from a different gNB than the one that the WTRU is associated with now), or pre-defined in the standards

At 411, the WTRU sends model assistance information to the gNB. The model assistance information may comprise WTRU capability information, and, for example, may include any of the following: Model type(s) WTRU is configured with, WTRU antenna configuration, WTRU positioning/location information, and/or Bandwidth part.

Next, at 413, the WTRU receives an indication of ML models (e.g., model ID) available at the gNB and the corresponding profile associated with each channel model, either as a response to the WTRU assistance indication 411 or broadcast in a SIB. The indication of each ML model may comprise any of: performance metric, threshold T; data distribution statistics (e.g., Doppler, SINR); and model parameters (e.g., size, latency, RS overhead).

At 415, the WTRU receives from the gNB the CSI-RS needed to compute channel estimates. Then, at 416, the WTRU uses the CSI-RS to compute the channel estimates using traditional channel estimation procedures. The WTRU also may measure other channel conditions (e.g., Doppler, SINR).

If, based on capabilities or radio conditions in the profile of the model, for example, the WTRU determines that no available trained model parameters match its requirements (e.g., the profiles of models at the gNB do not match the channel conditions just measured), the WTRU may send an indication 417 to the gNB that no current ML model fits its requirements, implicitly indicating to the gNB that it will be training its ML model. In an embodiment, the WTRU may include the condition that failed (e.g., SINR measured by the WTRU was not within range of the SINR of any model available at the gNB). Alternately (not shown), the indication of entering the training stage may be explicit.

Next, at 418, the WTRU calculates the weights of the ML model and updates the model accordingly. Computation of weights may be based on historical data if available, and may be periodic with periodicity set by the gNB. Alternately, the computation of weights may be event-triggered. The WTRU may update the weights based on CSI-RS transmissions for on-line training.

At 418, the WTRU then uses the updated ML model to obtain a ML-based CSI estimation. Furthermore, it computes an error e (e.g., NMSE) based on the difference between the CSI estimates output by the ML model and the CSI estimates from 416 calculated using traditional methods. The error may be computed either periodically, semi-periodically, or triggered by the gNB

If e>T, then the WTRU runs additional iterations to achieve convergence.

If e<T, then the WTRU, at 419, reports to the gNB the completion of ML model parameter calculation and supporting information, including data (statistics) on radio conditions used by the model for training.

Next, the WTRU may receive an ML model parameters transfer request 421 from the gNB. In response, at 423, the WTRU may transfer the ML model parameters to the gNB.

Finally, the WTRU may receive, at 425, an indication from the gNB that it has been selected as the basis for transfer learning (designated anchor WTRU) so that the WTRU may expect a model transfer request directly from another WTRU via SL.

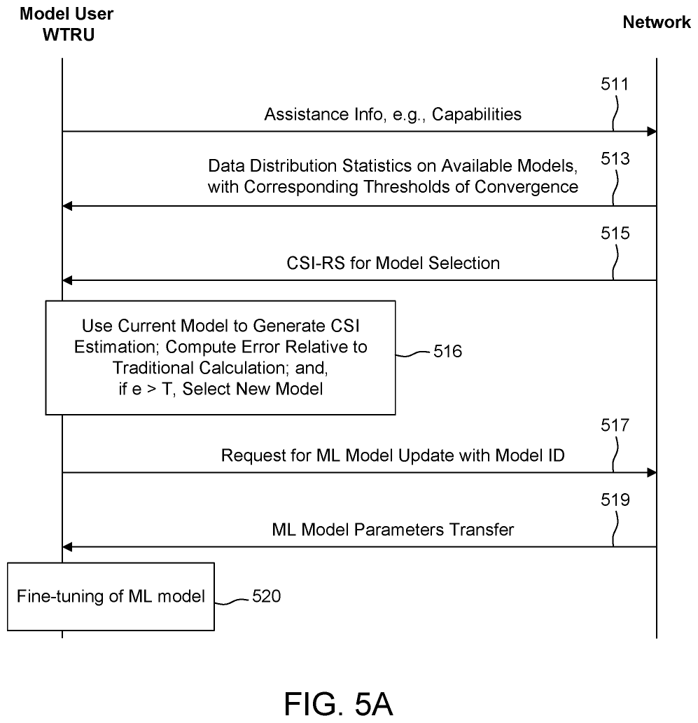

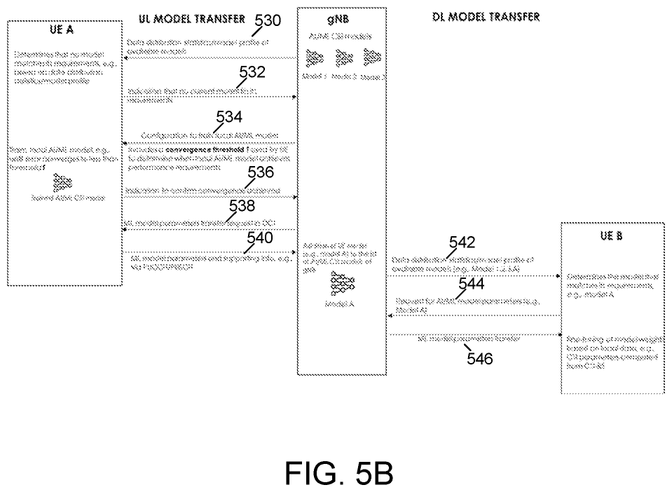

FIG. 5A is a signal flow diagram illustrating an example process for transferring a model from a model user or member WTRU to a network node or an anchor WTRU (e.g., model transfer in the DL), in accordance with an embodiment. Initially, in this example, an ML-capable WTRU is configured with one or more ML model(s) to perform channel estimation.

At 511, the WTRU sends assistance information to the gNB, which may include any one or more of: a list of (one of more) models WTRU is configured with (i.e., model IDs); antenna configuration; WTRU positioning/location information; and a BWP.

Next, at 513, the WTRU receives an indication of ML models (e.g., model ID) available at the gNB and the corresponding profile associated with each CHEST model, either as a response to the WTRU assistance indication 511 or as a broadcast in a SIB. The indication of each ML model may comprise any of the following: performance metric, threshold T for each ML model; data distribution statistics (e.g., Doppler range, SINR) linked to each model; and model parameters (e.g., size, latency, RS overhead).

At 515, the WTRU receives from the gNB the CSI-RS needed to compute channel estimates. Then at 516, the WTRU uses the current ML model to obtain an ML-based CSI estimation and computes an error e (e.g., NMSE) based on the difference between the CSI estimates using the ML model and CSI estimates using traditional methods. If e<T, then the WTRU determines that it does not require an ML model update, and no action need be taken. If, on the other hand, e>T, the WTRU determines that it requires ML model update, the WTRU selects a model whose data distribution most closely matches its environmental parameters (e.g., SINR, Doppler), and, at 517, the WTRU sends a ML model update request to the gNB (with model ID).

At 519 the WTRU receives a ML model update from the gNB. At 520, the WTRU may fine-tune the weights of the ML model using its local data (e.g., based on CSI parameters computed by WTRU from periodic/semi-periodic CSI-RS).

FIG. 5B is a signal flow diagram depicting a method and apparatuses for UL and/or DL model transfer from/to one or more UEs, according to an example embodiment. As illustrated in the example of FIG. 5B, the method may involve UL model transfer between a UE (UE A) and a network node, e.g., a gNB. In addition, the example of FIG. 5B may involve DL model transfer between the network node, e.g., gNB, and UE B. As shown in the example of FIG. 5B, UE A may receive, at 530, information that indicates one or more model profile(s) and/or data distribution statistics (e.g., data distribution statistics associated with each of the available models) of available models from the network node (e.g., gNB). In this example, UE A may determine that none of the available models matches UE A's requirements, e.g., based on the data distribution statistics and/or model profiles, and as discussed elsewhere herein. At 532, UE A may send an indication to the network node (e.g., gNB) to indicate that none of the currently available models meets UE A's requirements. At 534, UE A may receive configuration information indicating information for training a local AI/ML model. For example, the configuration information may include, among other information or parameters, a convergence threshold T that may be used by UE A to determine when the local AI/ML model achieves performance requirements. In this example, UE A may then train the local AI/ML model, for example until the error associated with the trained local AI/ML model converges to less than the convergence threshold T. At 536, UE A may send an indication to the network node (e.g., gNB) to confirm that convergence of the local AI/ML model has been achieved. At 538, UE A may receive a request to transfer ML model parameters, e.g., in DCI. At 540, UE A may send information indicating the ML model (e.g., model A) parameters and supporting information, e.g., via PUCCH/PUSCH. The network node (e.g., gNB) may then add the AI/ML model information (e.g., model A) received from UE A to the list of AI/ML models at the network (e.g., at the gNB).

As further illustrated in the example of FIG. 5B, certain embodiments may include DL model transfer between a network node (e.g., gNB) and a UE (UE B). For example, as shown at 542, the network node (e.g., gNB) may send information that indicates one or more model profile(s) and/or data distribution statistics (e.g., data distribution statistics associated with each of the available models) of available models to UE B. In this example, UE B may determine, from the received information, a model (e.g., model A) that matches UE B's requirements. Model A may be the trained version received at the network node (e.g., gNB) from UE A, or a modified and/or fine-tuned and/or trained and/or retrained and/or processed and/or preprocessed version of model A that was received from UE A. At 544, UE B may send, to the network node, a request for the AI/ML model parameters associated with the model that matches UE B's requirements (e.g., model A). At 546, the network node may transfer the requested ML model parameters to UE B. Then, in this example, UE B may fine tune the model weights (e.g., the weights received as part of the model parameters) based on local data, e.g., CSI parameters computed from CSI-RS.

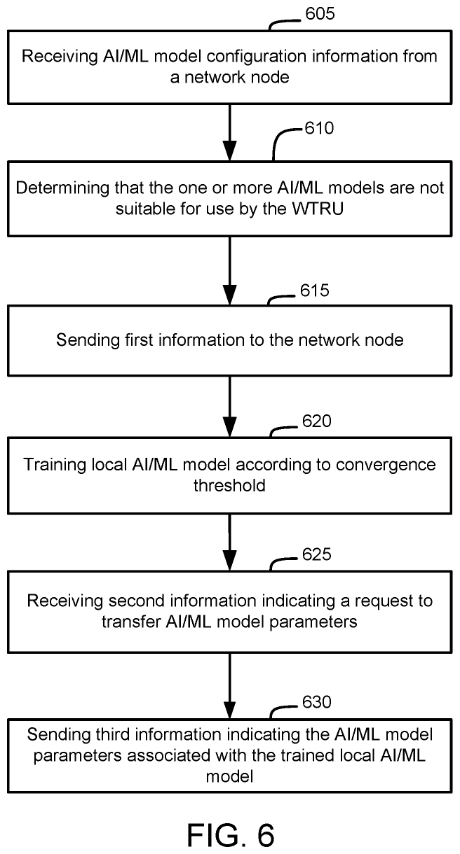

FIG. 6 is an example flow diagram illustrating an example method for the transfer, assessment, and/or training of AIML model(s), according to some embodiments. The example method of FIG. 6 and accompanying disclosures herein may be considered a generalization or synthetization of the various disclosures discussed above. For convenience and simplicity of exposition, the example of FIG. 6 may be described with reference to the architecture of the communications system 100 (FIG. 1). However, the example method depicted in FIG. 6 may be carried out using different architectures as well. According to some embodiments, the method of FIG. 6 may be implemented by a WTRU, such as WTRU 102. For example, the WTRU performing the example method of FIG. 6 may be an anchor WTRU, primary WTRU, or model trainer WTRU, for instance.

As illustrated in the example of FIG. 6, the method may include, at 605, receiving AI/ML model configuration information from a network node (e.g., base station or gNB). For example, the received model configuration information may indicate any of the following: one or more AI/ML models available from the network node, a profile associated with each respective one of the one or more AI/ML models (e.g., each of the AI/ML models may have a respective profile associated with it), and/or an AI/ML model training convergence threshold. For example, the AI/ML model profile (e.g., each of the profiles) may include any of: data distribution statistics and/or model parameters associated with the AI/ML models. Furthermore, the AI/ML model profiles may include additional information as discussed elsewhere herein. According to some embodiments, the configuration information may optionally include a trigger or command to determine whether the one or more AI/ML models are suitable for use for at least one function at the WTRU.

In some examples (not shown), the method may include the WTRU transmitting assistance information to the network node. For example, the assistance information may indicate any one or more of the following: capability information including model types that the WTRU is configured with, antenna configuration information for the WTRU, and/or location information for the WTRU.

In the example of FIG. 6, the method may include, at 610, determining that the one or more AI/ML models are not suitable for use by the WTRU. For example, the determining 610 may be based at least on the profile(s) associated with the respective AI/ML models. Additionally or alternatively, in certain embodiments, the determining 610 that the one or more AI/ML models are not suitable may be based on, but not limited to, measured radio conditions and any one or more of: the AI/ML model profiles, configured performance thresholds, and/or capabilities of the WTRU. It is noted that the determining 610 may be based on further parameters as discussed elsewhere herein. In some embodiments, the determining 610 may include comparing at least one measurement performed by the WTRU with the configured performance thresholds and, based on that comparison, determining that the one or more AI/ML models are not suitable.

As shown in the example of FIG. 6, the method may include, at 615, sending first information to the network node. The first information may indicate any of the following: the one or more AI/ML models are not suitable for the WTRU and/or that the WTRU will be training a local AI/ML model. In some embodiments, the first information may include an indication of a condition associated with the AI/ML model profile that was determined by the WTRU to have failed. For example, the failure of the condition may cause the WTRU to determine that the associated AI/ML model is not suitable for use by the WTRU. As one example, the failed condition may include, but is not limited to, signal-to-interference plus noise ratio (SINR) measured by the WTRU not being within range of the SINR of any of the models available from the network node. Other examples of conditions are discussed elsewhere herein. In some examples, the indication of the condition may be a cause code for indicating that the AI/ML model is not suitable for use by the WTRU. In various embodiments, the local AI/ML model may be a model stored and/or located at the WTRU and which may be used for lifecycle management stages, such as training, retraining, finetuning, inference, etc.

Referring to the example of FIG. 6, the method may include, at 620, training the local AI/ML model according to the convergence threshold. According to some embodiments, the training 620 of the local AI/ML model according to the convergence threshold may include determining an error from an output of the local AI/ML model and measured channel conditions. On condition that the error is greater than the convergence threshold, the training 620 may include performing additional iterations of the training to achieve convergence of the local AI/ML model. When the error is less than the convergence threshold, the method may include reporting completion of the training of the local AI/ML model to the network node.

In the example of FIG. 6, the method may include, at 625, receiving second information indicating a request, from the network node, to transfer AI/ML model parameters. As shown in the example of FIG. 6, the method may include, at 630, sending third information indicating the AI/ML model parameters associated with the trained local AI/ML model to the network node. As an example, the model parameters may include any one or more of: channel measurements associated with training the AI/ML models, static information associated with the AI/ML models, performance information associated with the AI/ML models, and/or training frequency associated with the AI/ML models. According to some embodiments, the sending 630 of the third information may further include sending channel data distribution statistics associated with training the AI/ML model parameters.

According to certain example embodiments, any of the one or more AI/ML models and/or the local AI/ML model are configured to perform CSI estimation. However, in various embodiments, the AI/ML model(s) may be configured to perform other functions associated with the WTRU, as discussed elsewhere herein.

Systems and methods for processing data according to representative embodiments may be performed by one or more processors executing sequences of instructions contained in a memory device. Such instructions may be read into the memory device from other computer-readable mediums such as secondary data storage device(s). Execution of the sequences of instructions contained in the memory device causes the processor to operate, for example, as described above. In alternative embodiments, hard-wire circuitry may be used in place of or in combination with software instructions to implement the present invention. Such software may run on a processor which is housed within a robotic assistance/apparatus (RAA) and/or another mobile device remotely. In the later a case, data may be transferred via wireline or wirelessly between the RAA or other mobile device containing the sensors and the remote device containing the processor which runs the software which performs the scale estimation and compensation as described above. According to other representative embodiments, some of the processing described above with respect to localization may be performed in the device containing the sensors/cameras, while the remainder of the processing may be performed in a second device after receipt of the partially processed data from the device containing the sensors/cameras.

Although features and elements are provided above in particular combinations, one of ordinary skill in the art will appreciate that each feature or element can be used alone or in any combination with the other features and elements. The present disclosure is not to be limited in terms of the particular embodiments described in this application, which are intended as illustrations of various aspects. Many modifications and variations may be made without departing from its spirit and scope, as will be apparent to those skilled in the art. No element, act, or instruction used in the description of the present application should be construed as critical or essential to the invention unless explicitly provided as such. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods or systems.

The foregoing embodiments are discussed, for simplicity, with regard to the terminology and structure of infrared capable devices, i.e., infrared emitters and receivers. However, the embodiments discussed are not limited to these systems but may be applied to other systems that use other forms of electromagnetic waves or non-electromagnetic waves such as acoustic waves.

It is also to be understood that the terminology used herein is for the purpose of describing particular embodiments only, and is not intended to be limiting. As used herein, the term “video” or the term “imagery” may mean any of a snapshot, single image and/or multiple images displayed over a time basis. As another example, when referred to herein, the terms “user equipment” and its abbreviation “UE”, the term “remote” and/or the terms “head mounted display” or its abbreviation “HMD” may mean or include (i) a wireless transmit and/or receive unit (WTRU); (ii) any of a number of embodiments of a WTRU; (iii) a wireless-capable and/or wired-capable (e.g., tetherable) device configured with, inter alia, some or all structures and functionality of a WTRU; (iii) a wireless-capable and/or wired-capable device configured with less than all structures and functionality of a WTRU; or (iv) the like. Details of an example WTRU, which may be representative of any WTRU recited herein, are provided herein with respect to FIGS. 1A-1D. As another example, various disclosed embodiments herein supra and infra are described as utilizing a head mounted display. Those skilled in the art will recognize that a device other than the head mounted display may be utilized and some or all of the disclosure and various disclosed embodiments can be modified accordingly without undue experimentation. Examples of such other device may include a drone or other device configured to stream information for providing the adapted reality experience.

In addition, the methods provided herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, MME, EPC, AMF, or any host computer.

Variations of the method, apparatus and system provided above are possible without departing from the scope of the invention. In view of the wide variety of embodiments that can be applied, it should be understood that the illustrated embodiments are examples only, and should not be taken as limiting the scope of the following claims. For instance, the embodiments provided herein include handheld devices, which may include or be utilized with any appropriate voltage source, such as a battery and the like, providing any appropriate voltage.

Moreover, in the embodiments provided above, processing platforms, computing systems, controllers, and other devices that include processors are noted. These devices may include at least one Central Processing Unit (“CPU”) and memory. In accordance with the practices of persons skilled in the art of computer programming, reference to acts and symbolic representations of operations or instructions may be performed by the various CPUs and memories. Such acts and operations or instructions may be referred to as being “executed,” “computer executed” or “CPU executed.”

One of ordinary skill in the art will appreciate that the acts and symbolically represented operations or instructions include the manipulation of electrical signals by the CPU. An electrical system represents data bits that can cause a resulting transformation or reduction of the electrical signals and the maintenance of data bits at memory locations in a memory system to thereby reconfigure or otherwise alter the CPU's operation, as well as other processing of signals. The memory locations where data bits are maintained are physical locations that have particular electrical, magnetic, optical, or organic properties corresponding to or representative of the data bits. It should be understood that the embodiments are not limited to the above-mentioned platforms or CPUs and that other platforms and CPUs may support the provided methods.

The data bits may also be maintained on a computer readable medium including magnetic disks, optical disks, and any other volatile (e.g., Random Access Memory (RAM)) or non-volatile (e.g., Read-Only Memory (ROM)) mass storage system readable by the CPU. The computer readable medium may include cooperating or interconnected computer readable medium, which exist exclusively on the processing system or are distributed among multiple interconnected processing systems that may be local or remote to the processing system. It should be understood that the embodiments are not limited to the above-mentioned memories and that other platforms and memories may support the provided methods.

In an illustrative embodiment, any of the operations, processes, etc. described herein may be implemented as computer-readable instructions stored on a computer-readable medium. The computer-readable instructions may be executed by a processor of a mobile unit, a network element, and/or any other computing device.

There is little distinction left between hardware and software implementations of aspects of systems. The use of hardware or software is generally (but not always, in that in certain contexts the choice between hardware and software may become significant) a design choice representing cost versus efficiency tradeoffs. There may be various vehicles by which processes and/or systems and/or other technologies described herein may be effected (e.g., hardware, software, and/or firmware), and the preferred vehicle may vary with the context in which the processes and/or systems and/or other technologies are deployed. For example, if an implementer determines that speed and accuracy are paramount, the implementer may opt for a mainly hardware and/or firmware vehicle. If flexibility is paramount, the implementer may opt for a mainly software implementation. Alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples include one or more functions and/or operations, it will be understood by those within the art that each function and/or operation within such block diagrams, flowcharts, or examples may be implemented, individually and/or collectively, by a wide range of hardware, software, firmware, or virtually any combination thereof. In an embodiment, several portions of the subject matter described herein may be implemented via Application Specific Integrated Circuits (ASICs), Field Programmable Gate Arrays (FPGAs), digital signal processors (DSPs), and/or other integrated formats. However, those skilled in the art will recognize that some aspects of the embodiments disclosed herein, in whole or in part, may be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein may be distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a CD, a DVD, a digital tape, a computer memory, etc., and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein may be integrated into a data processing system via a reasonable amount of experimentation. Those having skill in the art will recognize that a typical data processing system may generally include one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity, control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components included within, or connected with, different other components. It is to be understood that such depicted architectures are merely examples, and that in fact many other architectures may be implemented which achieve the same functionality. In a conceptual sense, any arrangement of components to achieve the same functionality is effectively “associated” such that the desired functionality may be achieved. Hence, any two components herein combined to achieve a particular functionality may be seen as “associated with” each other such that the desired functionality is achieved, irrespective of architectures or intermedial components. Likewise, any two components so associated may also be viewed as being “operably connected”, or “operably coupled”, to each other to achieve the desired functionality, and any two components capable of being so associated may also be viewed as being “operably couplable” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, where only one item is intended, the term “single” or similar language may be used. As an aid to understanding, the following appended claims and/or the descriptions herein may include usage of the introductory phrases “at least one” and “one or more” to introduce claim recitations. However, the use of such phrases should not be construed to imply that the introduction of a claim recitation by the indefinite articles “a” or “an” limits any particular claim including such introduced claim recitation to embodiments including only one such recitation, even when the same claim includes the introductory phrases “one or more” or “at least one” and indefinite articles such as “a” or “an” (e.g., “a” and/or “an” should be interpreted to mean “at least one” or “one or more”). The same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, the terms “any of” followed by a listing of a plurality of items and/or a plurality of categories of items, as used herein, are intended to include “any of,” “any combination of,” “any multiple of,” and/or “any combination of multiples of” the items and/or the categories of items, individually or in conjunction with other items and/or other categories of items. Moreover, as used herein, the term “set” is intended to include any number of items, including zero. Additionally, as used herein, the term “number” is intended to include any number, including zero. And the term “multiple”, as used herein, is intended to be synonymous with “a plurality”.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein may be readily broken down into a lower third, middle third and upper third, etc. As will also be understood by one skilled in the art all language such as “up to,” “at least,” “greater than,” “less than,” and the like includes the number recited and refers to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Moreover, the claims should not be read as limited to the provided order or elements unless stated to that effect. In addition, use of the terms “means for” in any claim is intended to invoke 35 U.S.C. § 112, ¶ 6 or means-plus-function claim format, and any claim without the terms “means for” is not so intended.

Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Application Specific Standard Products (ASSPs); Field Programmable Gate Arrays (FPGAs) circuits, any other type of integrated circuit (IC), and/or a state machine.

The WTRU may be used in conjunction with modules, implemented in hardware and/or software including a Software Defined Radio (SDR), and other components such as a camera, a video camera module, a videophone, a speakerphone, a vibration device, a speaker, a microphone, a television transceiver, a hands free headset, a keyboard, a Bluetooth® module, a frequency modulated (FM) radio unit, a Near Field Communication (NFC) Module, a liquid crystal display (LCD) display unit, an organic light-emitting diode (OLED) display unit, a digital music player, a media player, a video game player module, an Internet browser, and/or any Wireless Local Area Network (WLAN) or Ultra Wide Band (UWB) module.

Although the various embodiments have been described in terms of communication systems, it is contemplated that the systems may be implemented in software on microprocessors/general purpose computers (not shown). In certain embodiments, one or more of the functions of the various components may be implemented in software that controls a general-purpose computer.

In addition, although the invention is illustrated and described herein with reference to specific embodiments, the invention is not intended to be limited to the details shown. Rather, various modifications may be made in the details within the scope and range of equivalents of the claims and without departing from the invention.

### REFERENCES

The following references may have been referred to hereinabove and are incorporated in full herein by reference.
[1] 3GPP TS 38.214, “Physical layer procedures for data”, v16.0.0
[2] 3GPP TS 38.213, “Physical layer procedures for control”, v16.0.0
[3] 3GPP TS 38.212, “Multiplexing and channel coding”, v16.0.0
[4] 3GPP TS 38.211, “Physical Channels and Modulation”, v16.0.0
[5] 3GPP TS 38.331, “Radio Resource Control (RRC) protocol specification”, v16.0.0
[6] 3GPP TS 38.321, “Medium Access Control (MAC) protocol specification”, v16.0.0
[7] 3GPP TR 22.874, “Study on traffic characteristics and performance requirements for AI/ML model transfer in 5GS”, Rel-18, v18.2.0.

1. A wireless transmit/receive unit (WTRU), comprising:
circuitry, comprising any of a processor, memory, transmitter and receiver, configured to:
receive, from a network node, Artificial Intelligence/Machine Learning (AI/ML) model configuration information indicating: one or more AI/ML models available from the network node, one or more profiles associated with the one or more AI/ML models, respectively, and an AI/ML model training convergence threshold, wherein the one or more profiles comprise data distribution statistics and model parameters associated with the one or more AI/ML models;
based at least on the one or more profiles, determine that the one or more AI/ML models are not suitable for use by the WTRU;
send first information, to the network node, indicating any of: the one or more AI/ML models are not suitable for the WTRU and the WTRU will be training a local AI/ML model;
train the local AI/ML model according to the convergence threshold;
receive second information indicating a request, from the network node, to transfer AI/ML model parameters; and
send third information indicating the AI/ML model parameters associated with the trained local AI/ML model to the network node.

2. The WTRU of claim 1, wherein the one or more profiles comprises any of: data distribution statistics and model parameters associated with the AI/ML models, and
wherein the model parameters comprise any of
channel measurements associated with the AI/ML models;
static information associated with the AI/ML models;
performance information associated with the AI/ML models; and
training frequency associated with the AI/ML models.

3. (canceled)

4. The WTRU of claim 1, wherein the circuitry is configured to determine that the one or more AI/ML models are not suitable based on measured radio conditions and any of: the one or more profiles, configured performance thresholds, and capabilities of the WTRU.

5. The WTRU of claim 4, the circuitry configured to:
compare at least one measurement performed by the WTRU with the configured performance thresholds; and
based on the comparison, further determine that the one or more AI/ML models are not suitable.

6. The WTRU of claim 1, wherein, to train the local AI/ML model according to the convergence threshold, the circuitry is configured to:
determine an error from an output of the local AI/ML model and measured channel conditions;
on condition that the error is greater than the convergence threshold, perform additional iterations of the training to achieve convergence of the local AI/ML model;
on condition that the error is less than the convergence threshold, report completion of the training of the local AI/ML model to the network node.

7. The WTRU of claim 1, wherein the first information comprises an indication of a condition associated with the one or more profiles that was determined by the WTRU to have failed.

8. The WTRU of claim 7, wherein the failed condition comprises signal-to-interference plus noise ratio (SINR) measured by the WTRU not being within range of the SINR of any of the AI/ML models available from the network node.

9. The WTRU of claim 1, wherein the WTRU is configured to transmit assistance information to the network node, and wherein the assistance information indicates any of: capability information including AI/ML model types that the WTRU is configured with, antenna configuration information for the WTRU, and location information for the WTRU.

10. (canceled)

11. The WTRU of claim 1, wherein the configuration information comprises a trigger or command to determine whether the one or more AI/ML models are suitable for use for at least one function at the WTRU.

12. The WTRU of claim 1, wherein any of the one or more AI/ML models and the local AI/ML model are configured to perform any of channel state information (CSI) estimation or CSI prediction.

13. (canceled)

14. A method, implemented in a wireless transmit/receive unit (WTRU), the method comprising:
receiving, from a network node, AI/ML model configuration information indicating: one or more AI/ML models available from the network node, one or more profiles associated with the one or more AI/ML models, respectively, and an AI/ML model training convergence threshold, wherein the one or more profiles comprise data distribution statistics and model parameters associated with the one or more AI/ML models;
based at least on the one or more profiles, determining that the one or more AI/ML models are not suitable for use by the WTRU;
sending first information, to the network node, indicating: the one or more AI/ML models are not suitable for the WTRU and the WTRU will be training a local AI/ML model;
training the local AI/ML model according to the convergence threshold;
receiving second information indicating a request, from the network node, to transfer AI/ML model parameters; and
sending third information indicating the AI/ML model parameters associated with the trained local AI/ML model to the network node.

15. The method of claim 14, wherein the one or more profiles comprises any of: data distribution statistics and model parameters associated with the AI/ML models, and
wherein the model parameters comprise any of:
channel measurements associated with the AI/ML models;
static information associated with the AI/ML models;
performance information associated with the AI/ML models; and
training frequency associated with the AI/ML models.

16. (canceled)

17. The method of claim 14, wherein determining that the one or more AI/ML models are not suitable is based on measured radio conditions and any of: the one or more profiles, configured performance thresholds, and capabilities of the WTRU.

18. The method of claim 17, comprising:
comparing at least one measurement performed by the WTRU with the configured performance thresholds; and
based on the comparison, further determining that the one or more AI/ML models are not suitable.

19. The method of claim 14, wherein the training of the local AI/ML model according to the convergence threshold comprises:
determining an error from an output of the local AI/ML model and measured channel conditions;
on condition that the error is greater than the convergence threshold, performing additional iterations of the training to achieve convergence of the local AI/ML model;
on condition that the error is less than the convergence threshold, reporting completion of the training of the local AI/ML model to the network node.

20. The method of claim 14, wherein the first information comprises an indication of a condition associated with the one or more profiles that was determined by the WTRU to have failed.

21. The method of claim 20, wherein the failed condition comprises signal-to-interference plus noise ratio (SINR) measured by the WTRU not being within range of the SINR of any of the AI/ML models available from the network node.

22. The method of claim 14, comprising transmitting assistance information to the network node, and wherein the assistance information indicates any of: capability information including AI/ML model types that the WTRU is configured with, antenna configuration information for the WTRU, and location information for the WTRU.

23. (canceled)

24. The method of claim 14, wherein the configuration information comprises a trigger or command to determine whether the one or more AI/ML models are suitable for use for at least one function at the WTRU.

25. The method of claim 14, wherein any of the one or more AI/ML models and the local AI/ML model are configured to perform any of channel state information (CSI) estimation or CSI prediction.

26. (canceled)
